(19) United States
(12) Patent Application Publication
(10) Pub. No.: US 2014/0083614 A1
(43) Pub. Date: Mar. 27, 2014

(54) SUBSTRATE PROCESSING APPARATUS AND GAS SUPPLY APPARATUS

(71) Applicant: Tokyo Electron Limited, Tokyo (JP)

(72) Inventors: Masashi Itonaga, Kumamoto (JP); Yohei Sano, Beaverton, CO (US)

(73) Assignee: Tokyo Electron Limited, Tokyo (JP)

(21) Appl. No.: 14/031,785

(22) Filed: Sep. 19, 2013

(30) Foreign Application Priority Data
Sep. 25, 2012 (JP) 2012-211271

(51) Int. Cl. G03F 7/36

(52) U.S. Cl. CPC G03F 7/36
USPC 156/345.33

(57) ABSTRACT

The gas supply unit includes first gas flow paths having an upstream side communicated with a common first gas supply hole and diverged on the way to have a downstream side, and second gas flow paths having an upstream side communicated with a common second gas supply hole and diverged on the way to have a downstream side. A flow path length and a flow path diameter of each of the diverged first gas flow paths and the diverged second gas flow paths are set such that periods of time for gas flowing from the first gas supply hole to the respective first gas ejecting holes are matched with each other, and periods of time for gas flowing from the second gas supply hole to the respective second gas ejecting holes are matched with each other.

### CROSS-REFERENCE TO RELATED APPLICATIONS

This application is based on and claims priority from Japanese Patent Application No. 2012-211271, filed on Sep. 25, 2012, with the Japanese Patent Office, the disclosure of which is incorporated herein in its entirety by reference.

### TECHNICAL FIELD

The present disclosure relates to a substrate processing apparatus for processing a substrate by supplying a processing gas under a normal pressure atmosphere, and a gas supply apparatus used in the substrate processing apparatus.

### BACKGROUND

Due to the wave-like property of light irradiated on a resist film of a semiconductor wafer (hereinafter, referred to as a wafer) during an exposure processing, variation in measurement dimension, called Line Width Roughness (LWR) occurs in a resist pattern formed after the development. When the resist film in which the pattern is roughened is used as a mask to an undercoat film, the etching shape is influenced by the roughness. As a result, the shape of a circuit pattern formed by the etching becomes also rough. Thus, as the circuit pattern becomes miniaturized, the influence of the roughness of the shape of the circuit pattern increases on the quality of semiconductor devices. As a result, the yield may be reduced.

Accordingly, a planarization processing of a front surface of a resist pattern has been investigated in which the resist pattern is exposed to a solvent atmosphere, and the surface of the resist pattern is swelled and dissolved. Japanese Patent Laid-Open Publication No. 2005-19969 discloses an apparatus for performing such a processing in which a solvent gas is supplied from the upper side on a wafer disposed on a disposition unit within a processing chamber. The apparatus is configured such that the inside of a processing chamber is partitioned into upper and lower portions by a baffle plate formed with a plurality of holes, a disposition table is provided at the lower side of the baffle plate, and a solvent gas is supplied to the upper side of the baffle plate from a solvent supply unit. The solvent gas supplied to the upper side of the baffle plate in this manner flows through the baffle plate to the lower side, and is supplied to the entire surface of a wafer on the disposition table. With this configuration, the solvent gas may be supplied to the entire surface of the wafer, and thus may be supplied to the wafer surface uniformly to some extent. However, as the pattern becomes miniaturized, a requirement for precision of a pattern shape tends to be further strict. Thus, it is required to perform a processing with a higher in-plane uniformity on a wafer. See, e.g. paragraph [0065] and FIG. 15 of Japanese Patent Laid-Open Publication No. 2005-19969.

Specifically, the solvent gas supplied from the solvent supply unit into the processing chamber is diffused in an upper area above the baffle plate, while a part of the solvent gas flows to the lower side through the baffle plate. A purge gas or atmospheric air exists in the upper area to be substituted by the solvent gas atmosphere within the processing chamber after a preceding wafer has been processed. Accordingly, until the atmosphere of the purge gas or the atmospheric air of the upper area is substituted by the solvent gas, the solvent gas is ejected from the holes at a position close to the solvent supply unit but is not ejected from the holes at a position far away from the solvent supply unit. Thus, until the atmosphere of the upper area is substituted by the solvent gas, the amount of the supplied solvent gas is higher at the position close to the solvent supply unit than at the position far away from the solvent supply unit on the wafer surface.

This causes variation in concentration distribution of the solvent on the wafer surface. At the position close to the solvent supply unit, the solvent is supplied in a large amount with a high concentration. Thus, the resist pattern may be excessively swelled to be collapsed or dissolved. In particular, when the line width of the resist pattern is reduced to form a fine circuit pattern on the undercoat film, the ratio of a thickness of the solvent permeation area in relation to the thickness of the pattern increases. Thus, the pattern collapse or dissolution may easily occur. Meanwhile, at the position far away from the solvent supply unit, since the solvent gas is supplied in a small amount with a low concentration, the roughness of the resist pattern may not be sufficiently relieved.

### SUMMARY

The present disclosure provides a substrate processing apparatus including: a processing chamber configured such that a substrate is processed by a processing gas under a normal pressure atmosphere within the processing chamber; a disposition unit provided within the processing chamber and configured to dispose the substrate thereon; and a gas supply unit provided to supply the processing gas to the substrate disposed on the disposition unit and having a gas ejecting surface facing the substrate. The gas supply unit includes: a plurality of first gas ejecting holes and a plurality of second gas ejecting holes which are formed to be distributed over a first area and a second area of the gas ejecting surface, first gas flow paths having an upstream side communicated with a common first gas supply hole and diverged on the way to have a downstream side opened as the plurality of first gas ejecting holes, and second gas flow paths having an upstream side communicated with a common second gas supply hole and diverged on the way to have a downstream side opened as the plurality of second gas ejecting holes, the second gas flow paths being partitioned from the first gas flow paths. A flow path length and a flow path diameter of each of the diverged first gas flow paths and the diverged second gas flow paths are set such that periods of time for gas flowing from the first gas supply hole to the respective first gas ejecting holes are matched with each other, and periods of time for gas flowing from the second gas supply hole to the respective second gas ejecting holes are matched with each other.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional side view illustrating a solvent supply apparatus according to the present disclosure.

FIG. 2 is a horizontal cross-sectional plan view illustrating the solvent supply apparatus.

FIG. 3 is a schematic view illustrating a gas supply system of the solvent supply apparatus.

FIG. 4 is a vertical cross-sectional side view schematically illustrating a processing chamber of the solvent supply apparatus according to an exemplary embodiment.

FIG. 5 is a vertical cross-sectional perspective view schematically illustrating a part of the processing chamber.

FIG. 6 is a perspective view illustrating a cover of the processing chamber.

FIG. 7 is a perspective view illustrating a gas supply unit that constitutes the cover.

FIG. 8 is an exploded perspective view illustrating the gas supply unit.

FIG. 9 is a vertical cross-sectional side view illustrating first gas flow paths of the gas supply unit.

FIG. 10 is a plan view illustrating the first gas flow paths.

FIG. 11 is a vertical cross-sectional side view illustrating second gas flow paths of the gas supply unit.

FIG. 12 is a plan view illustrating the second gas flow paths.

FIG. 13 is a vertical cross-sectional side view illustrating third gas flow paths of the gas supply unit.

FIG. 14 is a plan view illustrating the third gas flow paths.

FIG. 15 is a top view illustrating a plate at the first tier that constitutes the top of the gas supply unit.

FIG. 16 is a bottom view illustrating the plate at the first tier.

FIG. 17 is a top view illustrating a plate at the second tier.

FIG. 18 is a top view illustrating a plate at the third tier.

FIG. 19 is a bottom view illustrating the plate at the third tier.

FIG. 20 is a top view illustrating a plate at the fourth tier.

FIG. 21 is a top view illustrating a plate at the fifth tier.

FIG. 22 is a bottom view illustrating the plate at the fifth tier.

FIG. 23 is a top view illustrating a plate at the sixth tier.

FIG. 24 is a top view illustrating a plate at the seventh tier.

FIG. 25 is a bottom view illustrating the plate at the seventh tier.

FIG. 26 is a top view illustrating a plate at the eighth tier.

FIG. 27 is a top view illustrating a plate at the ninth tier.

FIG. 28 is a bottom view illustrating the plate at the ninth tier.

FIG. 29 is a perspective view illustrating a part of the plates.

FIG. 30 is a process view illustrating processing in a processing unit.

FIG. 31 is a process view illustrating processing in the processing unit.

FIG. 32 is a process view illustrating processing in the processing unit.

FIG. 33 is a process view illustrating processing in the processing unit.

FIG. 34 is a vertical cross-sectional side view illustrating flows of a processing gas and a purge gas in the processing unit.

FIG. 35 is a schematic view illustrating the state of a resist pattern.

FIG. 36 is a vertical cross-sectional side view of a processing chamber according to another exemplary embodiment.

FIG. 37 is a characteristic graph illustrating a change of a supply flow rate of a processing gas with elapse of time.

FIG. 38 is a characteristic graph illustrating a change of a supply flow rate of a processing gas with elapse of time.

FIG. 39 is a characteristic graph illustrating a change of a supply flow rate of a processing gas with elapse of time.

FIG. 40 is a vertical cross-sectional side view illustrating a processing chamber according to a further exemplary embodiment.

FIG. 41 is a top view illustrating a plate that constitutes another gas supply unit.

FIG. 42 is a top view illustrating another plate that constitutes the gas supply unit.

FIG. 43 is a top view illustrating a further plate that constitutes the gas supply unit.

FIG. 44 is a cross-sectional side view illustrating the gas supply unit.

FIG. 45 is a top view illustrating a plate that constitutes a further gas supply unit.

FIG. 46 is a top view illustrating another plate that constitutes the gas supply unit.

FIG. 47 is a top view illustrating a further plate that constitutes the gas supply unit.

FIG. 48 is a top view illustrating a plate that constitutes a still further gas supply unit.

FIG. 49 is a top view illustrating another plate that constitutes the gas supply unit.

FIG. 50 is a top view illustrating a further plate that constitutes the gas supply unit.

FIG. 51 is a graph illustrating reference test results.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

The present disclosure has been made by taking the above-described problems into consideration. An object of the present disclosure is to provide a technology of performing processing on a substrate by supplying a processing gas from a gas supply unit facing the substrate under normal pressure atmosphere, in which concentrations of the processing gas on the substrate surface at the time of initiating the ejection of the processing gas from the gas supply unit may be matched to increase the in-plane processing uniformity the substrate.

According to a first aspect of the present disclosure, a substrate processing apparatus is provided. The substrate processing apparatus includes: a processing chamber configured such that a substrate is processed by a processing gas under a normal pressure atmosphere within the processing chamber; a disposition unit provided within the processing chamber and configured to dispose the substrate thereon; and a gas supply unit provided to supply the processing gas to the substrate disposed on the disposition unit and having a gas ejecting surface facing the substrate. The gas supply unit includes: a plurality of first gas ejecting holes and a plurality of second gas ejecting holes which are formed to be distributed over a first area and a second area of the gas ejecting surface, first gas flow paths having an upstream side communicated with a common first gas supply hole and diverged on the way to have a downstream side opened as the plurality of first gas ejecting holes, and second gas flow paths having an upstream side communicated with a common second gas supply hole and diverged on the way to have a downstream side opened as the plurality of second gas ejecting holes, the second gas flow paths being partitioned from the first gas flow paths. A flow path length and a flow path diameter of each of the diverged first gas flow paths and the diverged second gas flow paths are set such that periods of time for gas flowing from the first gas supply hole to the respective first gas ejecting holes are matched with each other, and periods of time for gas flowing from the second gas supply hole to the respective second gas ejecting holes are matched with each other.

In the substrate processing apparatus, between the first gas flow paths and the second gas flow paths, at least the first gas flow paths are formed to be diverged in a stepwise diagram shape that determines a tournament combination from the first gas supply hole to the respective first gas ejecting holes.

In the substrate processing apparatus, assuming that a direction perpendicular to the substrate is defined as a vertical direction, between the first gas flow paths and the second gas flow paths, at least the first gas flow paths include: a group of upper tier side flow paths that have a vertical flow path extending vertically and having an upper end side communicated with the first gas supply hole, and a plurality of horizontal flow paths extending horizontally and radially from a lower end side of the vertical flow path, and a group of lower tier side flow paths that have a plurality of vertical flow paths extending downwardly from downstream ends of the horizontal flow paths, respectively, in the group of the upper tier side flow paths, and a plurality of horizontal flow paths extending radially and horizontally from lower end sides of the vertical flow paths.

In the substrate processing apparatus, the gas supply unit includes a plurality of plates which are stacked one on another. The plurality of plates include a plate formed with groove portions or slits, and a plate formed with through holes that constitute the vertical flow paths, and the horizontal flow paths are formed by the groove portions or the slits formed on one plate together with a plate surface of another plate to be piled up on the plate.

In the substrate processing apparatus, the first area and the second area face a central area of the substrate, and a circumferential edge area of the substrate, respectively.

In the substrate processing apparatus, the processing performed on the substrate by supplying the processing gas is a processing performed to improve the roughness of a pattern mask formed on the substrate through exposure and development processings by supplying a solvent gas for dissolving a resist film on the substrate.

According to a second aspect, the present disclosure provides a substrate processing apparatus. The substrate processing apparatus includes: a processing chamber configured such that a substrate is processed by a processing gas under a normal pressure atmosphere within the processing chamber; a disposition unit provided within the processing chamber and configured to dispose the substrate thereon; and a gas supply unit provided to supply the processing gas to the substrate disposed on the disposition unit and having a gas ejecting surface facing the substrate. The gas supply unit includes: a plurality of first gas ejecting holes and a plurality of second gas ejecting holes which are formed to be distributed over a first area and a second area of the gas ejecting surface, first gas flow paths having an upstream side communicated with a common first gas supply hole and diverged on the way to have a downstream side opened as the plurality of first gas ejecting holes, the first gas flow paths being configured by using a plurality of plates which are stacked in a direction perpendicular to the substrate, and second gas flow paths having an upstream side communicated with a common second gas supply hole, and diverged on the way to have a downstream side opened as the plurality of second gas ejecting holes, the second gas flow paths being configured by using the plurality of plates and partitioned from the first gas flow paths. Assuming that a direction perpendicular to the substrate is defined as a vertical direction, the first gas flow paths and the second gas flow paths each include: a group of upper tier side flow paths that have a vertical flow path extending vertically and having an upper end side communicated with the first gas supply hole or the second gas supply hole, and a plurality of horizontal flow paths extending horizontally and radially from a lower end side of the vertical flow path, and a group of lower tier side flow paths that have a plurality of vertical flow paths extending downwardly from downstream ends of the horizontal flow paths, respectively, in the group of the upper tier side flow paths, and a plurality of horizontal flow paths extending radially and horizontally from lower end sides of the vertical flow paths. The plurality of plates include a plate formed with groove portions or slits and a plate formed with through holes that constitute the vertical flow paths, and the horizontal flow paths are formed by the groove portions or the slits formed on one plate together with a plate surface of another plate to be piled up on the plate. Flow path lengths of the first gas flow paths from the first gas supply hole to the respective first gas ejecting holes are matched with each other, and flow path lengths of the second gas flow paths from the second gas supply hole to the respective second gas ejecting holes are matched with each other.

In the substrate processing apparatus, a flow path length and a flow path diameter of each of the diverged first gas flow paths and the diverged second gas flow paths are set such that periods of time for gas flowing from the first gas supply hole to the respective first gas ejecting holes are matched with each other, and periods of time for gas flowing from the second gas supply hole to the respective second gas ejecting holes are matched with each other.

In the substrate processing apparatus, the first area and the second area face a central area of the substrate, and a circumferential edge area of the substrate, respectively.

In the substrate processing apparatus, the processing performed on the substrate by supplying the processing gas is a processing performed to improve the roughness of a pattern mask formed on the substrate through exposure and development processings by supplying a solvent gas for dissolving a resist film on the substrate.

According to a third aspect, the present disclosure provides a gas supply apparatus. The gas supply apparatus includes: a processing container set to a normal pressure atmosphere and configured such that a processing gas is supplied to a substrate disposed within the processing container; a gas ejecting surface facing the substrate disposed within the processing container; a plurality of first gas ejecting holes and a plurality of second gas ejecting holes which are formed to be distributed over a first area and a second area of the gas ejecting surface, respectively, first gas flow paths having an upstream side communicated with a common first gas supply hole and diverged on the way to have a downstream side opened as the plurality of first gas ejecting holes, and second gas flow paths having an upstream side communicated with a common second gas supply hole and diverged on the way to have a downstream side opened as the plurality of second gas ejecting holes, the second gas flow paths being partitioned from the first gas flow paths. A flow path length and a flow path diameter of each of the diverged first gas flow path and the diverged second gas flow path are set such that periods of time for gas flowing from the first gas supply hole to the respective first gas ejecting holes are matched with each other, and periods of time for gas flowing from the second gas supply hole to the respective second gas ejecting holes are matched with each other.

According to a still fourth aspect, the present disclosure provides a gas supply apparatus. The gas supply apparatus includes: a processing container set to a normal pressure atmosphere and configured such that a processing gas is supplied to a substrate disposed within the processing container; a gas ejecting surface facing the substrate disposed within the processing container; a plurality of first gas ejecting holes and a plurality of second gas ejecting holes which are formed to be distributed over a first area and a second area of the gas ejecting surface, respectively, first gas flow paths having an upstream side communicated with a common first gas supply hole and diverged on the way to have a downstream side opened as the plurality of first gas ejecting holes, the first gas flow paths being configured by using a plurality of plates which are stacked in a direction perpendicular to the substrate, and second gas flow paths having an upstream side communicated with a common second gas supply hole and diverged on the way to have a downstream side opened as the plurality of second gas ejecting holes, the second gas flow paths being configured by using the plurality of plates and partitioned from the first gas flow paths. Assuming that a direction perpendicular to the substrate is defined as a vertical direction, each of the first gas flow paths and the second gas flow paths includes: a group of upper tier side flow paths that have a vertical flow path extending vertically and having an upper end side communicated with the first gas supply hole or the second gas supply hole, and a plurality of horizontal flow paths extending horizontally and radially from a lower end side of the vertical flow path, and a group of lower tier side flow paths which have a plurality of vertical flow paths extending downwardly from downstream ends of the horizontal flow paths, respectively, in the group of the upper tier side flow paths, and a plurality of horizontal flow paths extending radially and horizontally from lower end sides of the vertical flow paths. The plurality of plates include a plate formed with groove portions or slits and a plate formed with through holes that constitute the vertical flow paths, and the horizontal flow paths are formed by the groove portions or the slits formed on one plate together with a plate surface of another plate to be piled up on the plate form the horizontal flow paths. Flow path lengths of the first gas flow paths from the first gas supply hole to the respective first gas ejecting holes are matched with each other, and flow path lengths of the second gas flow paths from the second gas supply hole to the respective second gas ejecting holes are matched with each other.

In the present disclosure, a flow path length and a flow path diameter of gas flow paths are set such that periods of time for gas flowing to the respective first gas ejecting holes from the first gas supply hole provided at the first area of the gas ejecting surface match each other, and periods of time for gas flowing to the respective second gas ejecting holes from the second gas supply hole provided at the second area of the gas ejecting surface match each other, For this reason, the timings when the processing gas reaches the respective gas ejecting holes within the first area and the second area each immediately after initiating the ejection of the processing gas are matched. That is, periods of time when the atmosphere (for example, a purge gas or an atmospheric air) within flow paths is substituted with the processing gas are matched from one gas supply hole to the respective gas ejecting holes connected to the corresponding gas supply hole. Accordingly, by appropriately controlling the flow rate of a gas to be supplied from each gas supply hole, the in-plane uniformity of the processing gas concentration on the substrate surface may be improved. This may improve the in-plane processing uniformity of the substrate.

In another aspect, flow path lengths of the first gas flow paths are matched from the first gas supply hole to the respective first gas ejecting holes, and flow path lengths of the second gas flow paths are matched from the second gas supply hole to the respective second gas ejecting holes. Accordingly, variation may be suppressed in timings when the processing gas reaches the respective gas ejecting holes within the first area and the second area each as described above, thereby improving the in-plane processing uniformity of the substrate.

### First Exemplary Embodiment

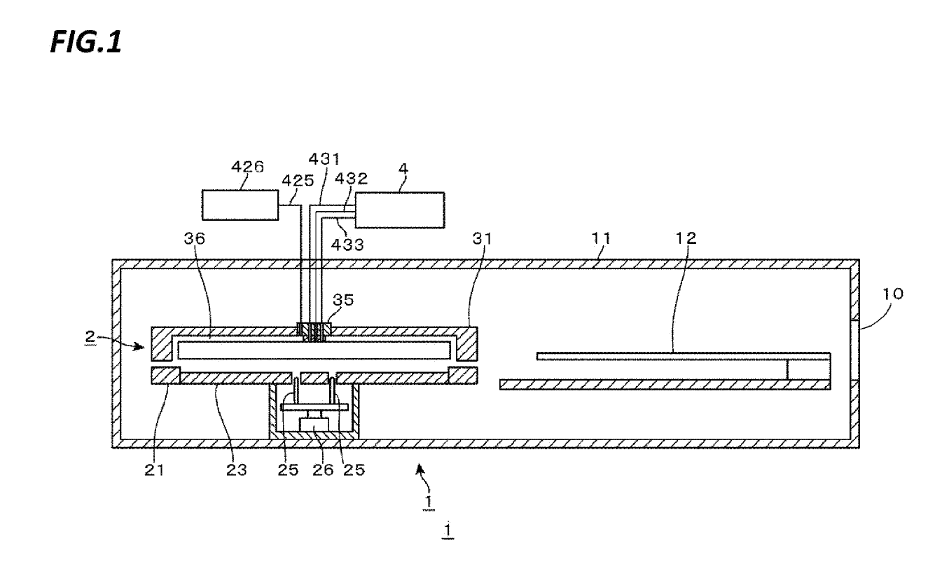

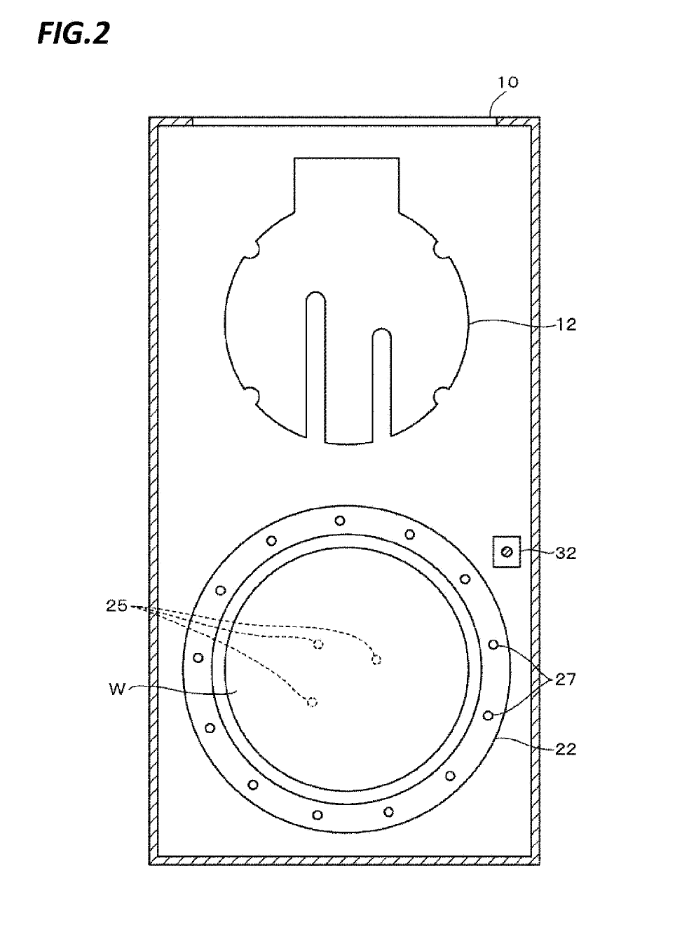

A solvent supply apparatus 1, to which a substrate processing apparatus of the present disclosure is employed, will be described with reference to FIGS. 1 to 3. The solvent supply apparatus 1 is provided under the normal pressure atmosphere, includes a case 11, and a processing chamber 2 provided within the case 11, and supplies a processing gas to a wafer W which is a substrate within the processing chamber 2. On a front surface of the wafer W, a resist film is formed, and the resist film has a resist pattern which is a pattern mask that is formed through exposure and developing processings. The processing gas includes a solvent gas, by which a smoothing process is performed to remove roughness on the front surface of the resist pattern through dissolution of the front surface. In the drawings, the reference numeral 12 indicates a plate, which moves between a stand-by position outside the processing chamber 2 as illustrated in FIGS. 1 and 2 and the inside of the processing chamber 2 to convey the wafer W. In the drawings, the reference numeral 10 indicates a conveyance opening of the wafer W, which is provided in the case 11.

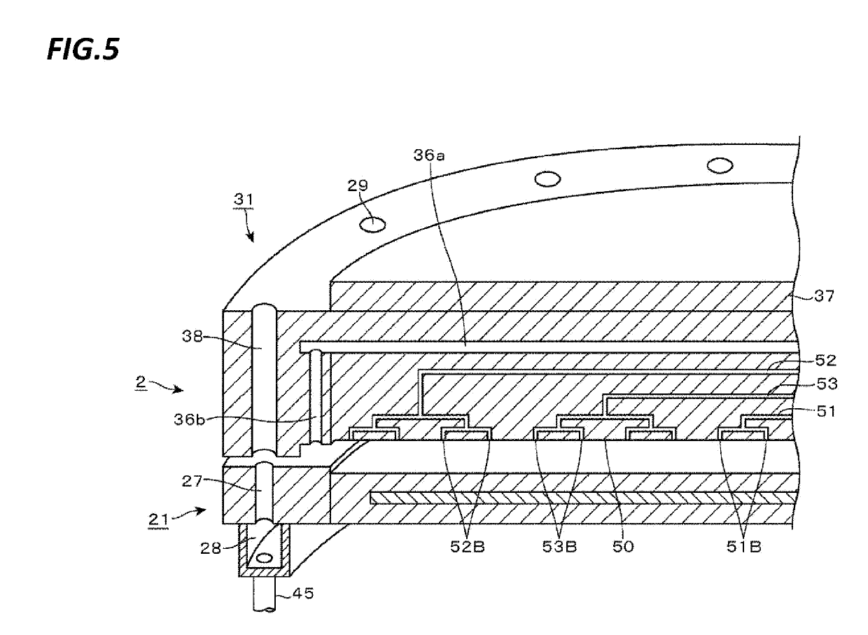

The processing chamber 2 is formed in, for example, a flat circular shape. The processing chamber 2, as illustrated in FIGS. 1 to 5, includes a container body 21 and a cover 31. The container body 21 includes a side wall portion 22 that forms a peripheral edge of the container body 21, and a disposition unit 23 that forms a lower wall portion surrounded by the side wall portion 22. The wafer W is horizontally disposed on the top surface of the disposition unit 23. A heater 24 is provided in the disposition unit 23, and heats the disposed wafer W to a predetermined temperature. In the drawings, the reference numeral 25 indicates pins, and the reference numeral 26 indicates an elevating mechanism. The pins 25 project from or retract into the disposition unit 23 by the elevating mechanism 26 to deliver the wafer W to/from the plate 12.

A plurality of purge gas flow paths 27 are formed along the circumferential direction in the side wall portion 22 to vertically penetrate the side wall portion 22. In the drawings, the reference numeral 28 indicates a space configured to introduce a purge gas. The space 28 is formed along the circumference of the side wall portion 22 below the side wall portion 22. Purge gas supply tubes 411 are opened at the space 28.

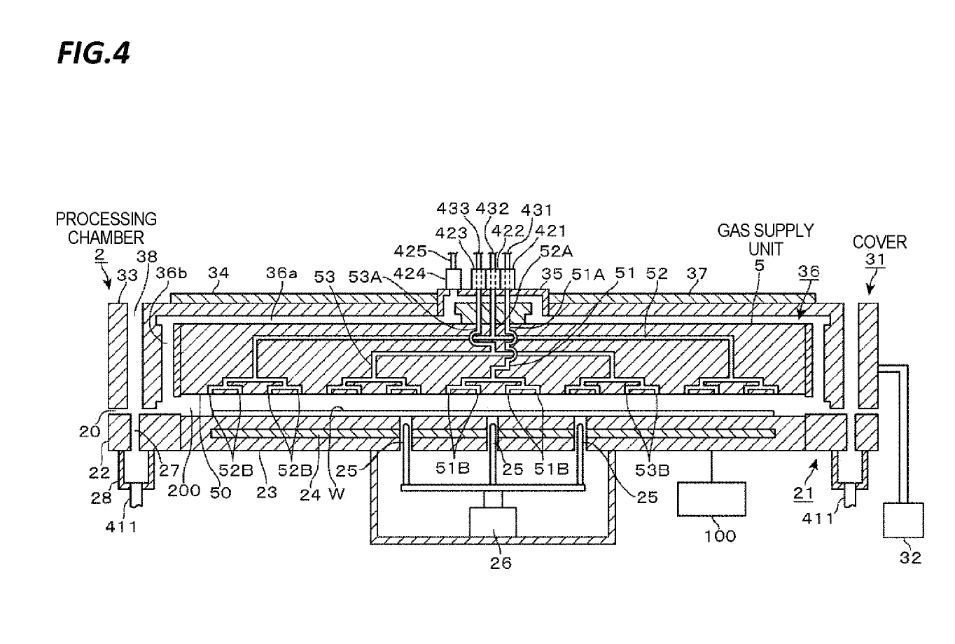

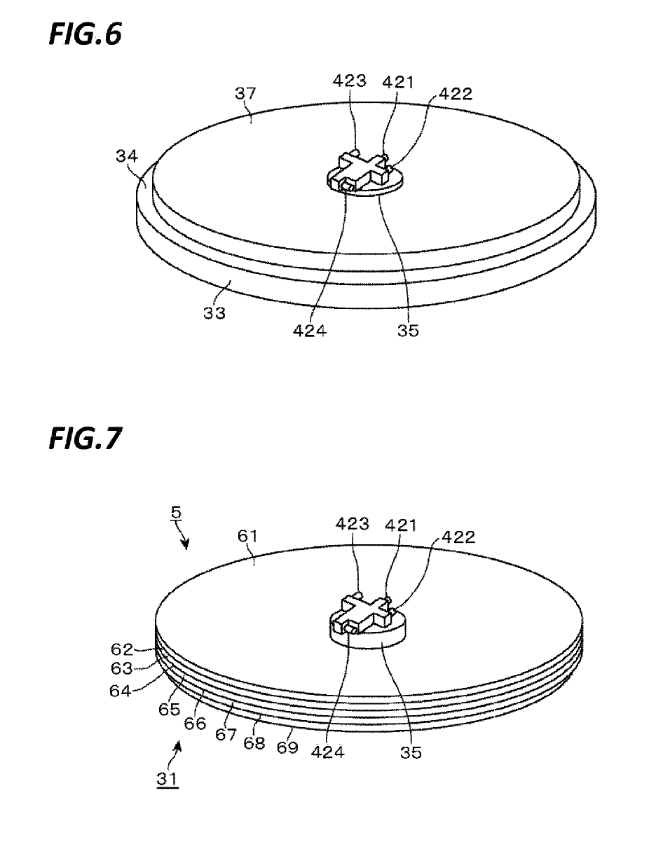

Referring to FIG. 6 which is a perspective view of the cover 31, the cover 31 will be described. The cover 31 is configured to be movable up and down by an elevating mechanism 32 from a carrying-in/out position where the wafer W is carried into the processing chamber 2, to a processing position where the wafer W is processed (the position illustrated in FIG. 4). The cover 31 includes a side wall portion 33 that forms the peripheral edge of the cover 31, an upper wall portion 34 surrounded by the side wall portion 33, and a circular gas flow path forming unit 35 provided at the center of the upper wall portion 34. The lower end of the side wall portion 33 is placed at a position lower than the lower end of the upper wall portion 34. When the cover 31 is placed at the processing position so as to perform a processing of the wafer W, the lower end of the upper wall portion 34 and the upper end of the side wall portion 22 of the container body 21 come close to each other with a gap 20 therebetween. In this manner, a processing area 200 is formed within the processing chamber 2 when the cover 31 is placed at the processing position.

A gas supply unit (shower head) 5 is provided within the cover 31 so as to form an exhaust space 36a between the upper wall portion 34 and the gas supply unit 5. Exhaust holes 36b are formed in the side wall portion 33, which have lower ends opened at the space between the side wall portion 33 and the container body 21, and upper ends communicated with the exhaust space 36a. The exhaust holes 36b are formed to be spaced apart from each other in the circumferential direction, and constitute an exhaust passage 36 together with the exhaust space 36a. Accordingly, the atmosphere within the processing area 200 is exhausted through the exhaust holes 36b which are spaced apart from each other in the circumferential direction to surround the processing area 200. Also, purge gas flow paths 38 are provided at the outside of the exhaust holes 36b, which vertically penetrate the side wall portion 33 so as to overlap the purge gas flow paths 27 of the container body 21. The purge gas flows from the purge gas flow paths 27 to the purge gas flow paths 38. Meanwhile, in FIG. 6, illustration of the purge gas flow paths 38 is omitted.

A heater 37 that constitutes a heating mechanism is provided in the upper wall portion 34 so as to suppress a solvent in the processing gas from being condensed in the exhaust space 36a, and the inside of the exhaust space 36a is heated up to a temperature higher than the dew point of the solvent (e.g. 80° C.).

The gas flow path forming unit 35 includes pipe connecting parts 421 to 423, and a pipe connection part 424. Gas supply tubes 431 to 433 are connected to the pipe connecting parts 421 to 423, each of which introduces the processing gas to each of gas supply holes 51A to 53A of the gas supply unit 5 to be described later. A gas supply system 4 to be described later is provided at an upstream side of the gas supply tubes 431 to 433. An exhaust mechanism 426 provided with, for example, a vacuum pump or a flow control valve, is connected to the pipe connection part 424 via an exhaust tube 425, and allows the exhaust passage 36 to be exhausted. For the convenience of illustration, the pipe connecting parts 421 to 423, and 424 are simply illustrated in FIG. 4, as compared to in FIG. 6.

The gas supply unit 5 corresponds to a gas supply apparatus of the present disclosure. The gas supply unit 5 is formed into a circular shape, and has the gas flow path forming unit 35 provided at the top center thereof. The gas supply unit 5 includes a gas ejecting surface 50 that faces the wafer W disposed on the disposition unit 23. The gas ejecting surface 50 is formed in, for example, a circular shape in a plan view. The size of the gas ejecting surface 50 in the plan view is larger than the wafer W on the disposition unit 23.

First gas flow paths 51, second gas flow paths 52 and third gas flow paths 53 which are partitioned from each other are formed within the gas supply unit 5. In FIG. 4, for easy understanding, the first gas flow paths 51 to the third gas flow paths 53 are schematically illustrated.

The first gas flow paths 51 have an upstream end configured as the gas supply hole 51A, and a downstream side diverged into a plurality of flow paths. That is, the gas supply hole 51A is commonly provided to the plurality of flow paths. The downstream ends of the first gas flow paths 51 form a plurality of gas ejecting holes 51B in the gas ejecting surface 50, and are opened toward the wafer W.

The second gas flow paths 52 have an upstream end configured as the gas supply hole 52A, and a downstream side diverged into a plurality of flow paths. The downstream ends of the second gas flow paths 52 form a plurality of gas ejecting holes 52B in the gas ejecting surface 50, and are opened toward the wafer W.

The third gas flow paths 53 also has the same configuration as those in the first gas flow paths 51 and the second gas flow paths 52. That is, the upstream end is configured as the gas supply hole 53A, and the downstream side is diverged to be opened as a plurality of gas ejecting holes 53B in the gas ejecting surface 50 toward the wafer W.

The gas ejecting holes 51B, 52B, and 53B are formed to be distributed over the entire surface of an area of the gas ejecting surface 50 facing the wafer W. The phrase “to be distributed over the entire surface of an area facing the wafer W” means that the gas ejecting holes 51B, 52B, and 53B are formed to be distributed so that the outermost one of the gas ejecting holes is positioned on the gas ejecting surface 50, outside an area facing the to-be-processed area (e.g. an area to be formed with devices) of the wafer W on the disposition unit 23.

The gas ejecting holes 51B are disposed in the central area of the gas ejecting surface 50, and the gas ejecting holes 52B are disposed in the circumferential edge area of the gas ejecting surface 50, respectively, by which a gas is ejected to each of the central area and the circumferential edge area of the wafer W. The gas ejecting holes 53B are disposed at the outside of a disposition area (first area) of the gas ejecting holes 51B, and at the inside of a disposition area (second area) of the gas ejecting holes 52B, in the gas supply unit 5. Hereinafter, for convenience, when the gas supply unit 5 and wafer W are radially divided into three areas in this manner, an area between the central area and the circumferential edge area may be referred to as an intermediate area. That is, the gas ejecting holes 53B are disposed in the intermediate area of the gas ejecting surface 50, and eject a gas to the intermediate area of the wafer W.

In the first gas flow paths 51, a flow path length and a flow path diameter (the cross-sectional area of a flow path) of the diverged gas flow paths are set so that periods of time for gas flowing from the gas supply hole 51A to the respective gas ejecting holes 51B are matched with each other. In the second gas flow paths 52, a flow path length and a flow path diameter (the cross-sectional area of a flow path) of the diverged gas flow paths are set so that periods of time for gas flowing from the gas supply hole 52A to the respective gas ejecting holes 52B are matched with each other. In the third gas flow paths 53, a flow path length and a flow path diameter (the cross-sectional area of a flow path) of the diverged gas flow paths are set so that periods of time for gas flowing from the gas supply hole 53A to the respective gas ejecting holes 53B are matched with each other. The first gas flow paths 51 to the third gas flow paths 53 may be matched or unmatched in terms of periods of time for gas flowing from the gas supply holes to the gas ejecting holes. Accordingly, the first gas flow paths 51 to the third gas flow paths 53 may be identical or different in terms of a flow path length, a flow path diameter, and a flow path volume.

The first gas flow paths 51 to the third gas flow paths 53 each are formed to be diverged in a stepwise diagram shape that determines a tournament combination from the gas supply hole 51A to 53A to the gas ejecting holes 51B to 53B. They include a combination of vertical flow paths which vertically extend, and horizontal flow paths, when a direction perpendicular to the wafer W is defined as a vertical direction.

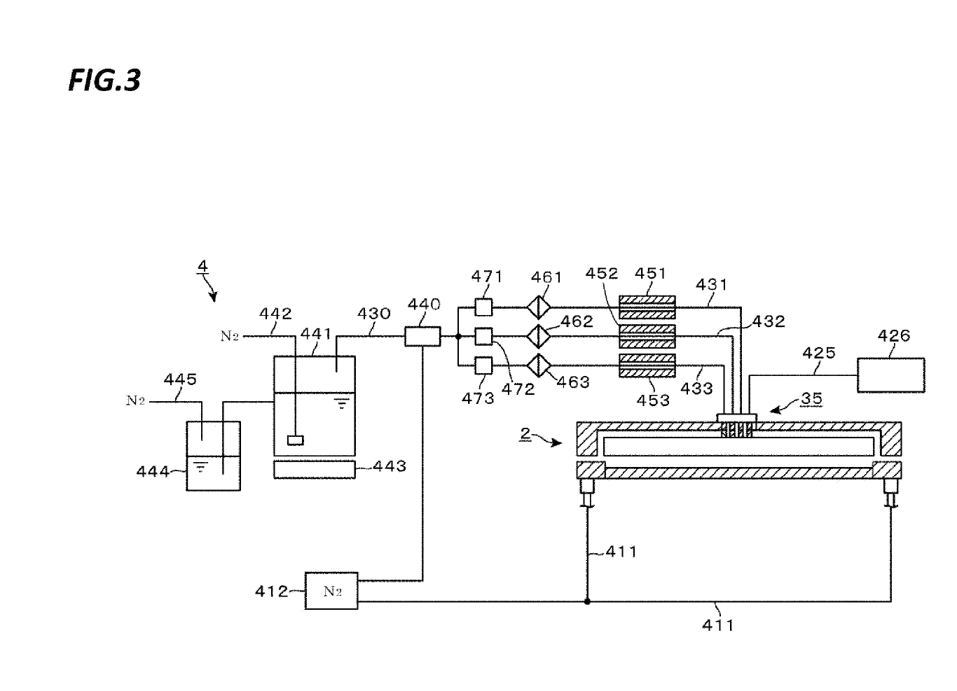

Before further describing the gas supply unit 5, the gas supply system 4 that supplies a gas to the gas supply unit 5 will be described with reference to FIG. 3. The upstream sides of the gas supply tubes 431, 432 and 433 are joined to constitute a junction tube 430, and the junction tube 430 is connected to a vaporization tank 441. In the vaporization tank 441, a solvent capable of swelling a resist through dissolution (e.g. NMP (N-methyl-2-pyrrolidone)) is contained. The vaporization tank 441 includes a gas supply tube 442 that is configured to perform bubbling by blowing, for example, N₂ gas into the vaporization tank 441, and a heater 443 that is configured to heat the solvent up to a predetermined temperature. The solvent vaporized by the bubbling is pumped, as the processing gas, together with N₂ gas, to the junction tube 430. In the drawing, the reference numeral 444 indicates a tank as a supply source of the solvent. When the inside of the tank 444 is pressurized by N₂ gas from a N₂ gas supply tube 445, the solvent is pumped from the tank 444 to the vaporization tank 441.

A three-way valve 440 is provided at the junction tube 430, and switches the connection terminal of the gas supply tubes 431 to 433 between the vaporization tank 441 and an N₂ gas supply source 434. N₂ gas from the N₂ gas supply source 434 is supplied, as a purge gas for purging the inside of the processing chamber 2, to the gas supply tubes 431 to 433. The purge gas serves to suppress the leakage of the processing gas to the outside of the processing chamber 2 by substituting for a processing gas atmosphere within the processing chamber 2 before a processed wafer W is carried out by moving up the cover 31 from the processing position. The N₂ gas supply source 434 is connected to the purge gas supply tubes 411 of the container body 21.

Heaters 451 to 453 are provided in the gas supply tubes 431 to 433, respectively, in which the heaters 451 to 453 suppress condensation of the solvent in the processing gas that flows in the respective tubes. Particle removing filters 461 to 463 and flow control units 471 to 473 are provided in this order at the upstream sides in the gas supply tubes 431 to 433, respectively. The flow control units 471 to 473 control flow rates of the processing gas and the purge gas (N₂ gas) to be supplied to the first gas flow paths 51 to the third gas flow paths 53 of the gas supply unit 5 based on a control signal of a control unit 100 to be described later.

If the processing gas is supplied at the same flow rate to the first gas flow paths 51 to the third gas flow paths 53, a gradient in concentration distribution of the processing gas may occur between the central area side and the circumferential edge area side of the wafer W during the processing of the wafer W due to various factors such as, for example, the design or processing precision of the processing chamber 2. This may causes variation in the degree of improvement of a resist pattern roughness. Accordingly, in order to suppress such variation in the degree of improvement, the flow control units 471 to 473 are allowed to separately set the flow rates of the gas to be supplied to the first gas flow paths 51 to the third gas flow paths 53. For example, a test wafer is subjected to a processing, and its LWR is measured. Based on the measurement result, the flow rates of the gas to be supplied are set.

As long as the variation in the degree of improvement of the pattern roughness is suppressed, the flow rates of the processing gas to be supplied to the first gas flow paths 51 to the third gas flow paths 53 may be identical to or different from each other.

The solvent supply apparatus 1 is provided with the control unit 100 including a computer. The control unit 100 transmits control signals to respective units of the solvent supply apparatus 1, and controls supply/interruption of various gases and flow rates of respective gases to be supplied, temperatures of various heaters, the delivery of the wafer W between the plate 12 and the disposition unit 23, and operations such as exhaustion within the processing chamber 2. Also, the control unit 100 is provided with a program that incorporates instructions (respective steps) to perform a processing in the solvent supply apparatus 1 as described below. The program is stored in a computer storage medium, such as, for example, a flexible disk, a compact disk, a hard disk, an MO (magneto-optical disk), and installed in the control unit 100.

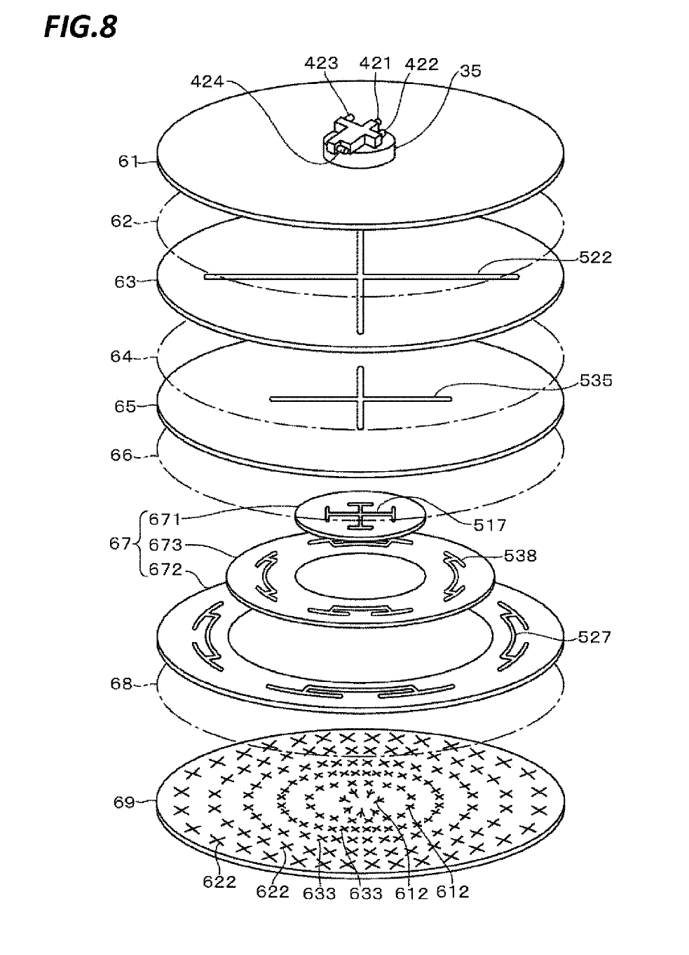

Subsequently, the gas supply unit 5 will be described in more detail. FIG. 7 illustrates the cover 31 in a state where the upper wall portion 34 and the side wall portion 33 are removed, and the gas supply unit 5 is exposed. FIG. 8 is an exploded perspective view illustrating the gas supply unit 5. The gas supply unit 5 is constituted by plates 61 to 69 which are stacked in 9 tiers. The plates 61 to 69 are formed in circular shapes, and concentrically overlap each other. The plates 68 and 69 at eighth and ninth tiers from the top are formed in a slightly smaller size than the plates 61 to 67 at the upper tiers.

The plate 67 at the seventh tier from the top is constituted by plates 671, 672, and 673 which include three divisions of a circle. The plate 671 is formed in a circular shape, and the plates 672 and 673 are formed in a ring shape and are disposed concentrically on the center of the plate 671. The plates 672 and 673 have different diameters, and the plate 672 is positioned at the outside of the plate 673.

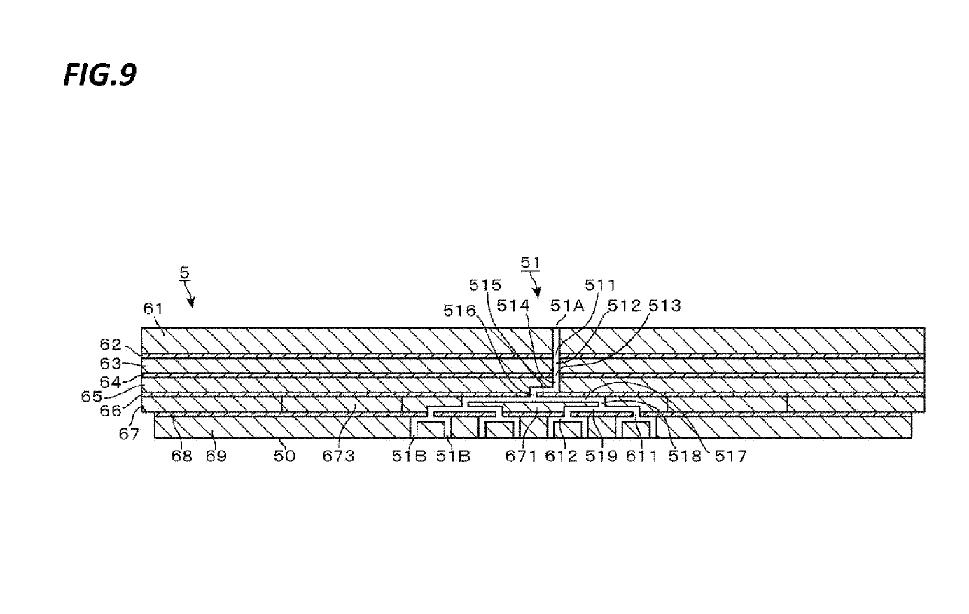

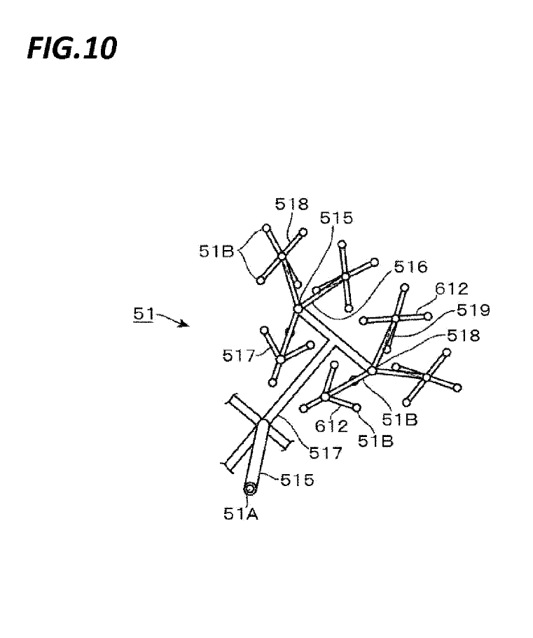

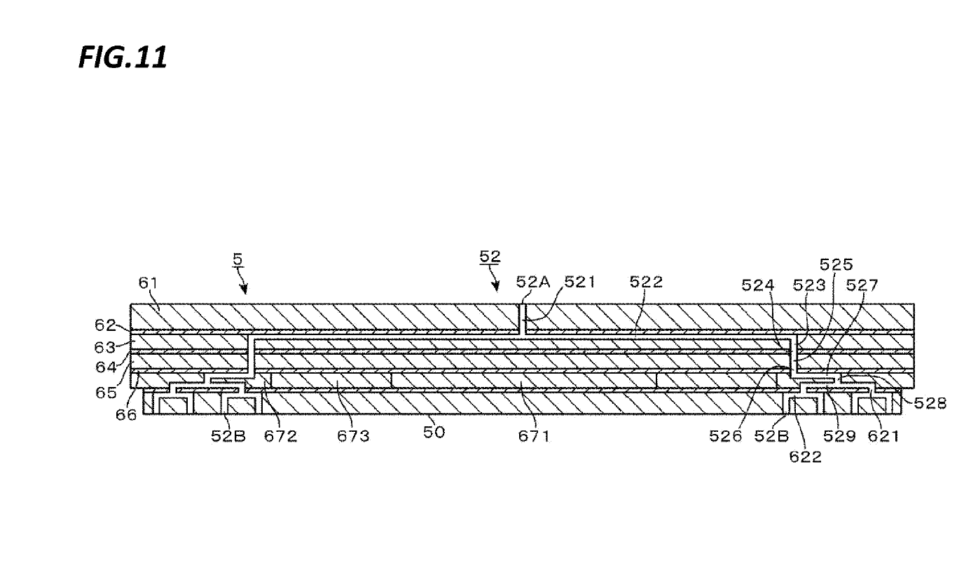

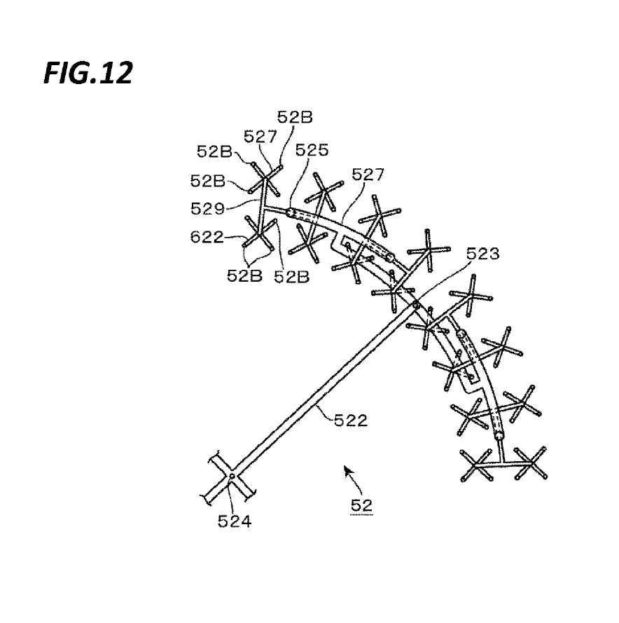

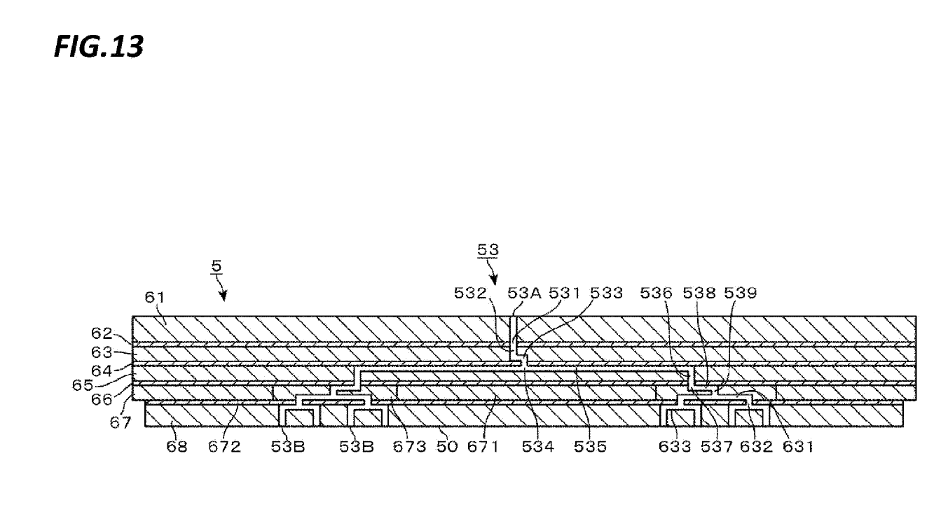

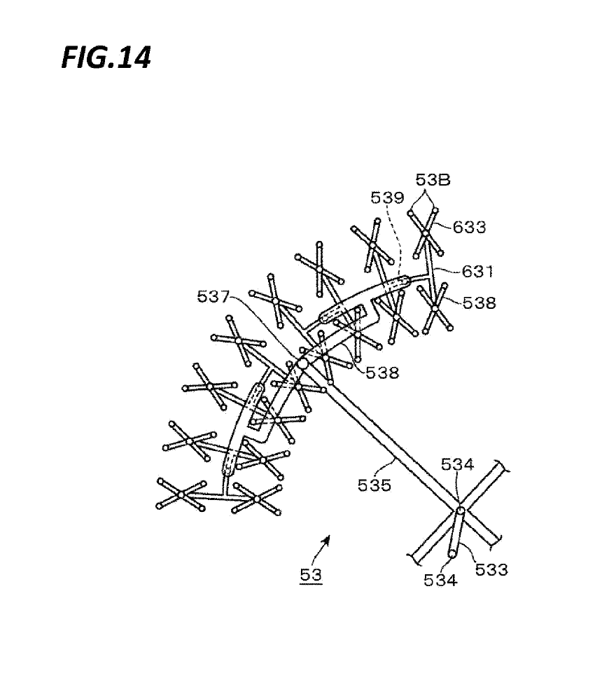

The plates 61, 63, 65, 67, and 69 are made of, for example, stainless steel, and have grooves or holes perforated in the thickness direction of the respective plates. The plates 62, 64, 66, and 68 are made of, for example, polytetrafluoroethylene, and have holes perforated in the thickness direction of the plates. The grooves and the holes overlap to form the first gas flow paths 51 to the third gas flow paths 53. FIGS. 9 and 10 are a vertical cross-sectional side view and a plan view illustrating the first gas flow paths 51, respectively. FIGS. 11 and 12 are a vertical cross-sectional side view and a plan view illustrating the second gas flow paths 52, respectively. FIGS. 13 and 14 are a vertical cross-sectional side view and a plan view illustrating the third gas flow paths 53, respectively. The grooves of the respective plates form the horizontal flow paths in the first gas flow paths 51 to the third gas flow paths 53, and the holes of the respective plates form the vertical flow paths in the first gas flow paths 51 to the third gas flow paths 53.

The respective plates will be described. In the respective drawings, the center of the plates is indicated by P. FIGS. 15 and 16 illustrate a top surface and a bottom surface of the plate 61 at the uppermost tier, respectively. Three holes are formed in the central area of the plate 61 to form the gas supply holes 51A to 53A of the first gas flow paths 51 to the third gas flow paths 53. The gas supply hole 52A is positioned at the center of the plate 61.

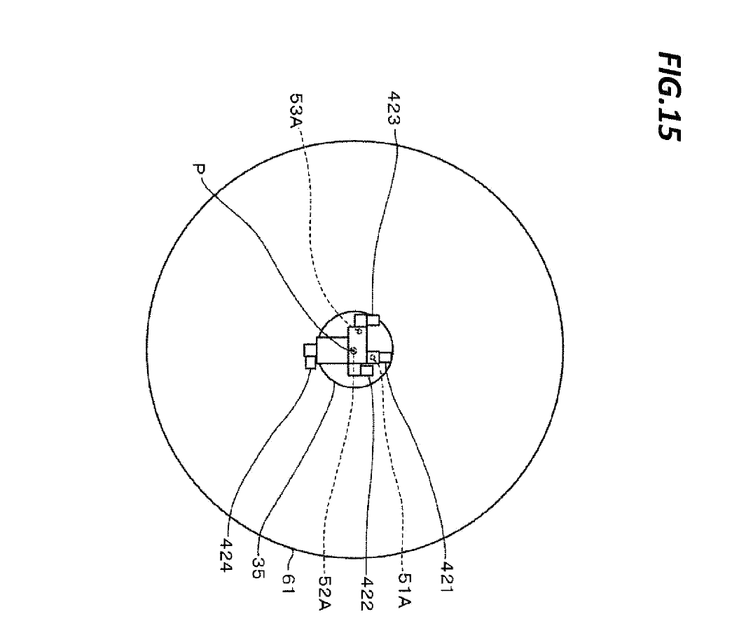

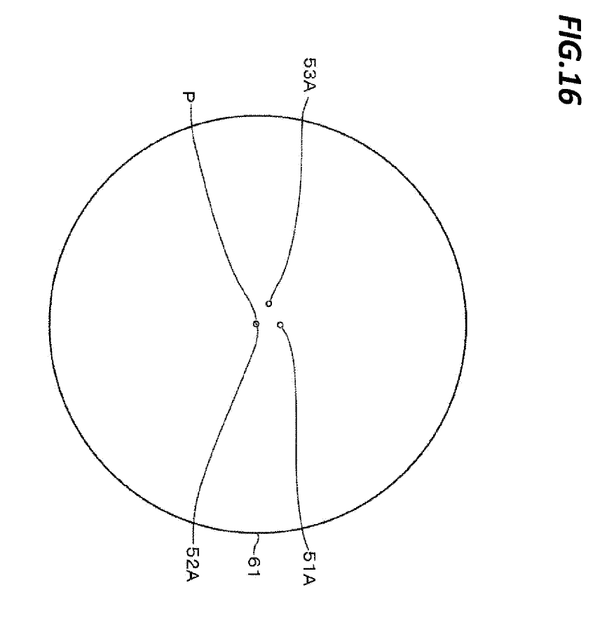

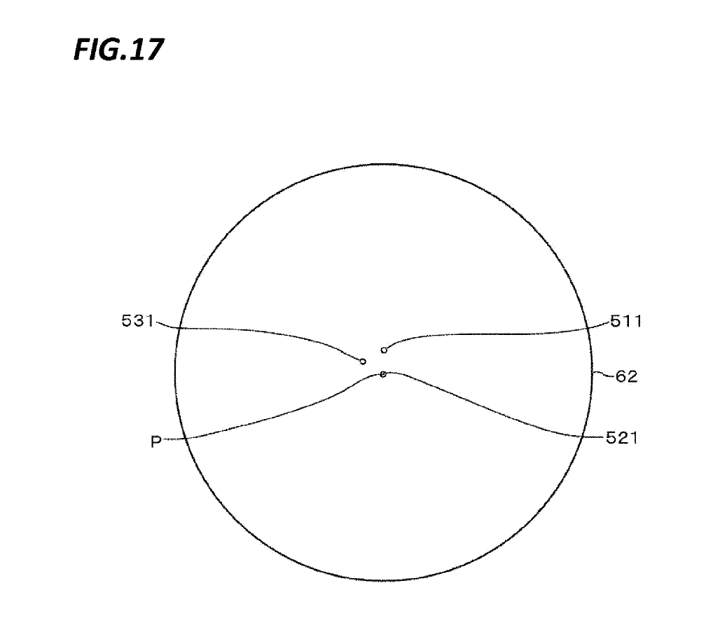

FIG. 17 is a plan view illustrating the plate 62 at the second tier from the top. Holes 511, 521 and 531 are formed to overlap the gas supply holes 51A, 52A, and 53A of the plate 61, respectively.

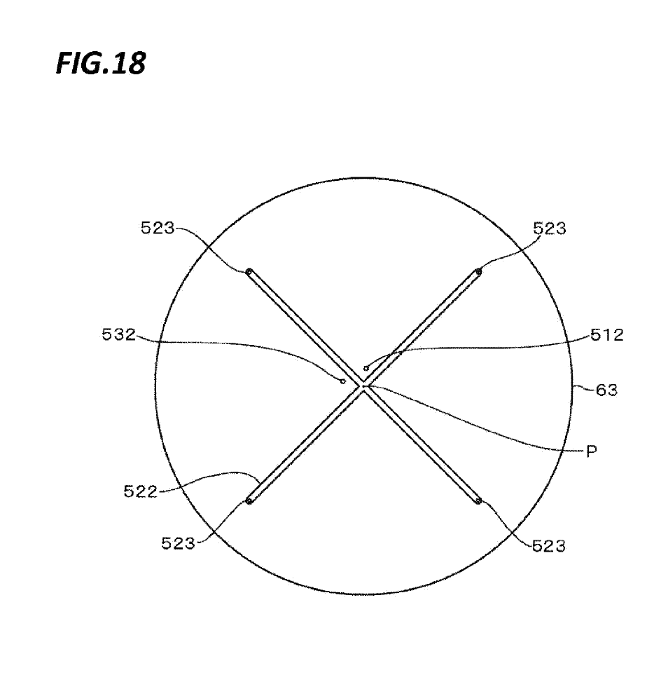

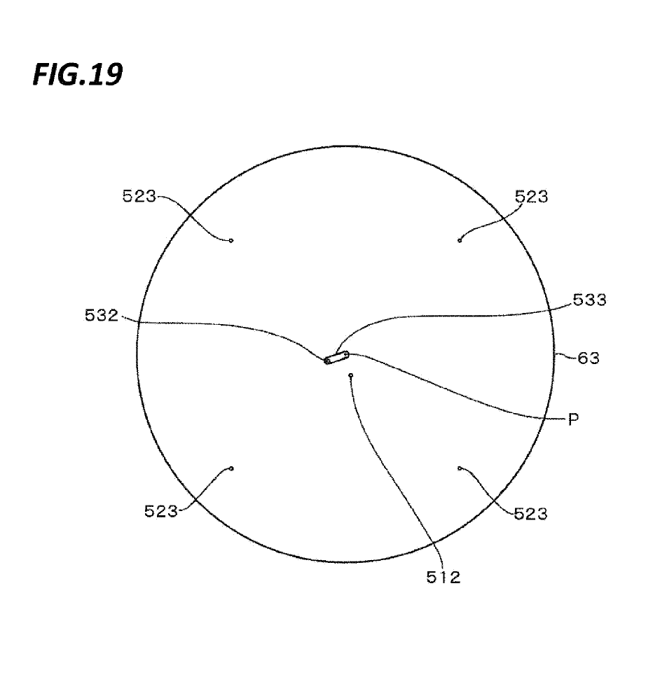

FIGS. 18 and 19 illustrate a top surface and a bottom surface of the plate 63 at the third tier from the top, respectively. Cross-shaped grooves 522 are formed on the top surface of the plate 63, which are diverged from the center of the plate 63 and have ends that extend radially in four directions. The grooves 522 form the second gas flow paths 52, and holes 523 are opened at the respective ends of the grooves 522. The hole 521 of the plate 62 is opened at the center of the grooves 522.

Also, holes 512 and 532 that form the first gas flow paths 51 and the third gas flow paths 53 are perforated in the plate 63 to overlap the holes 511 and 531 of the plate 62, respectively.

A straight groove 533 is formed on the bottom surface of the plate 63, and the hole 532 is opened at one end of the groove 533. The other end of the groove 533 extends to the center of the plate 63.

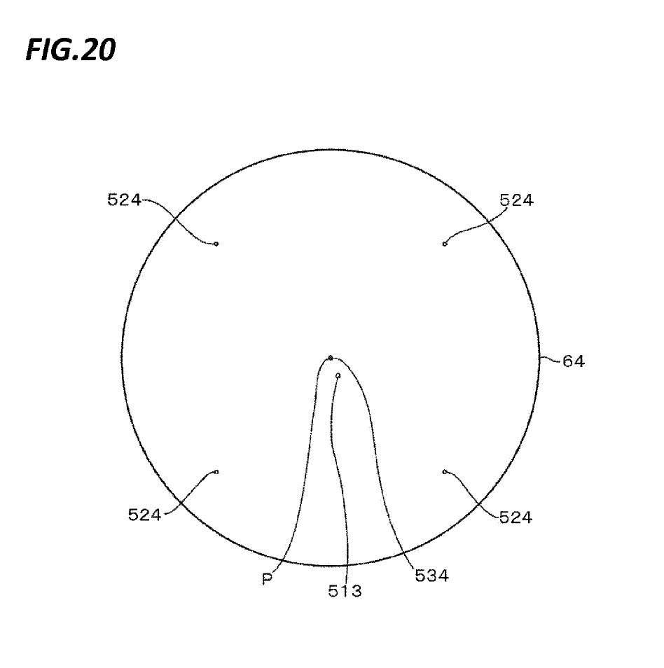

FIG. 20 is a plan view illustrating the plate 64 at the fourth tier from the top. Holes 513 and 524 that constitute the first gas flow paths 51 and the second gas flow paths 52, respectively, are formed in the plate 64, at positions overlapping the holes of 512 and 523 of the plate 63.

Also, a hole 534 that forms the third gas flow paths 53, is formed to be opened at the center P, that is, the other end of the groove 533 of the plate 63.

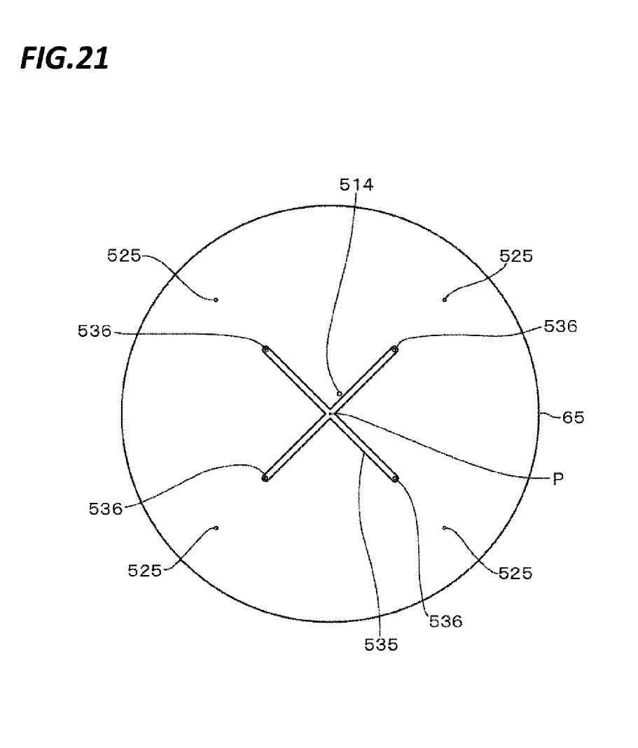

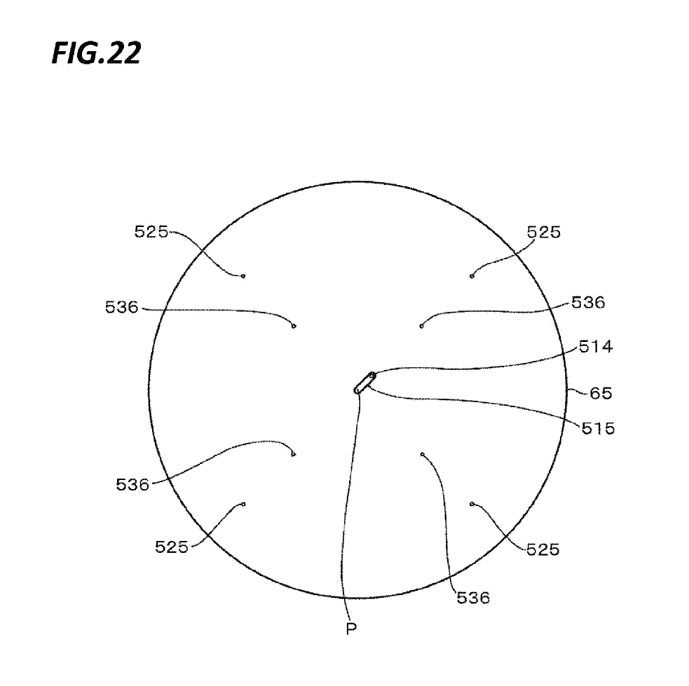

FIGS. 21 and 22 illustrate a top surface and a bottom surface of the plate 65 at the fifth tier from the top, respectively. Cross-shaped grooves 535 are formed on the top surface of the plate 65, which have ends diverged from the center P in four directions. That is, the hole 534 of the plate 64 is opened at the center of the grooves 535. Holes 536 are formed at the respective ends of the grooves 535.

Also, holes 514 and 525 that constitute the first gas flow paths 51, and the second gas flow paths 52 are formed in the plate 65 to overlap the holes 513 and 524 of the plate 64, respectively. A straight groove 515 is formed on the bottom surface of the plate 65, and the hole 514 is opened at one end of the groove 515. The other end of the groove 515 extends to the center of the plate 65.

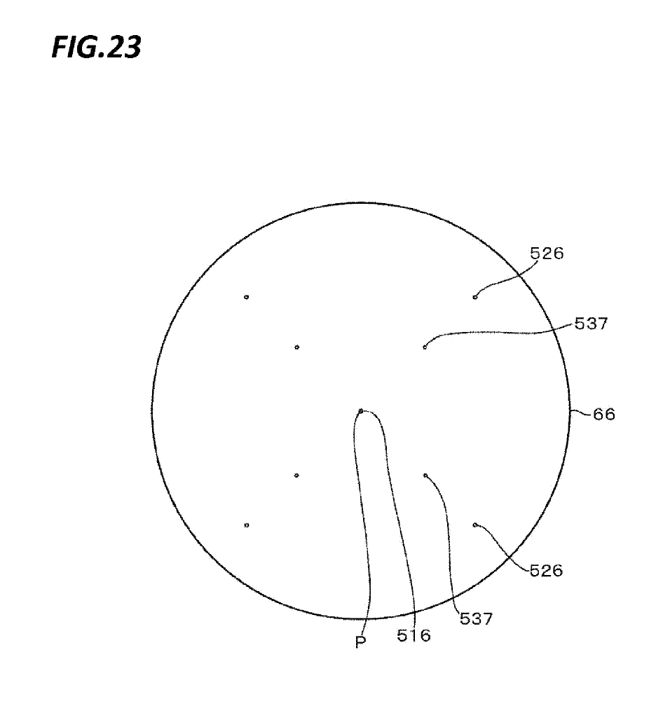

FIG. 23 is a plan view illustrating the plate 66 at the sixth tier from the top. Holes 526, and 537 that constitute the second gas flow paths 52, and the third gas flow paths 53, respectively, are formed in the plate 66, at positions overlapping the holes of 525, and 534 of the plate 65. Also, a hole 516 that forms the first gas flow paths 51, is formed to be opened at the center P, that is, the other end of the groove 515 of the plate 65.

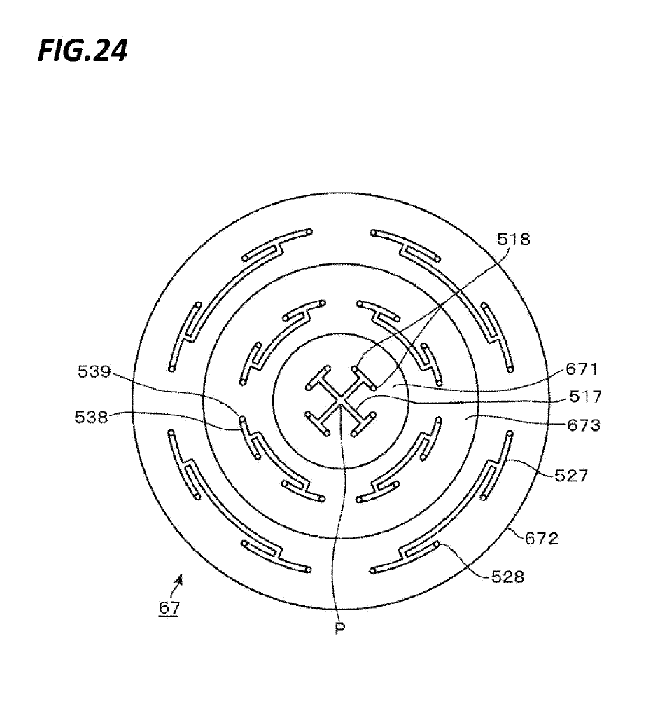

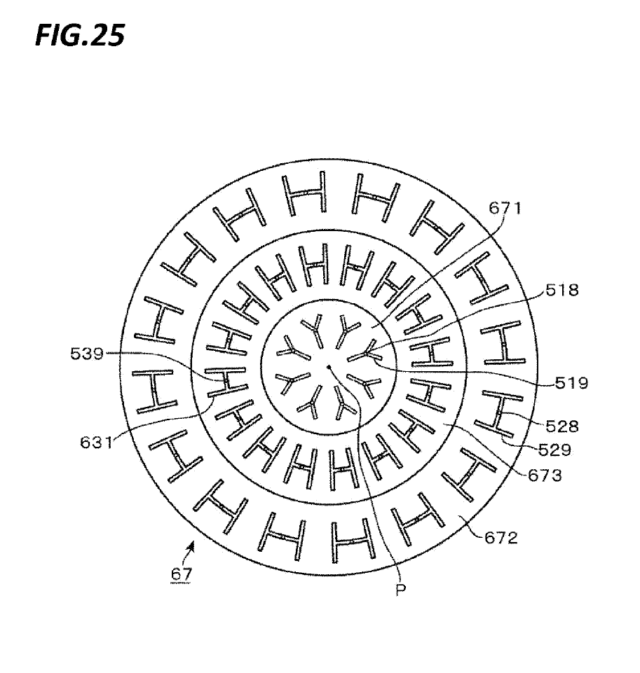

FIGS. 24 and 25 illustrate a top surface and a bottom surface of the plate 67 (671 to 673) at the seventh tier from the top, respectively. As illustrated in the drawings, the plate 67 is configured in four-fold symmetry. The plates 671, 672, and 673 form the first gas flow paths 51, the second gas flow paths 52, and the third gas flow paths 53, respectively.

Grooves 517 are formed on the top surface of the plate 671, which have ends extending from the center P in four directions, and each of the ends of the grooves 517 is formed to be diverged in two directions. That is, when viewed from the center P, the ends of the grooves 517 are diverged into 8 branches. The hole 516 of the plate 66 is opened at the center P as the junction of the grooves 517. Holes 518 are formed at the respective ends diverged from the grooves 517.

A plurality of grooves 519 are formed on the bottom surface of the plate 671 along the circumferential direction of the plate 671, each of which has ends extending from the junction in three directions, and is formed in a substantially Y shape. The holes 518 are opened at junctions of the grooves 519.

Four grooves 527 are formed on the top surface of the plate 672, each of which has ends extending from the junction along the circumferential direction of the plate 672. Both ends of each of the grooves 527 are drawn to the circumferential edge area side of the plate 672, and then diverged into two directions to extend in the circumferential direction. That is, when viewed from the junction, ends of each of the grooves 527 are diverged into four branches, and holes 528 are formed at the respective ends. Grooves 529 are formed on the bottom surface of the plate 672, and the holes 528 are opened within the grooves 529. Each of the grooves 529 extends from the junction formed with each of the holes 528 to the both sides of the plate 672 in the circumferential direction, and diverged from the both sides in two directions to be directed to the inside and the outside of the plate 672, respectively, which is formed in a substantially H shape from the plan view.

The same grooves and same holes are formed on the top surface and the bottom surface of the plate 673 as those of the plate 672. The grooves on the top surface of the plate 673 are indicated by the reference numeral 538, the holes formed at the grooves 538 are indicated by the reference numeral 539, and the grooves on the bottom surface are indicated by the reference numeral 631, respectively.

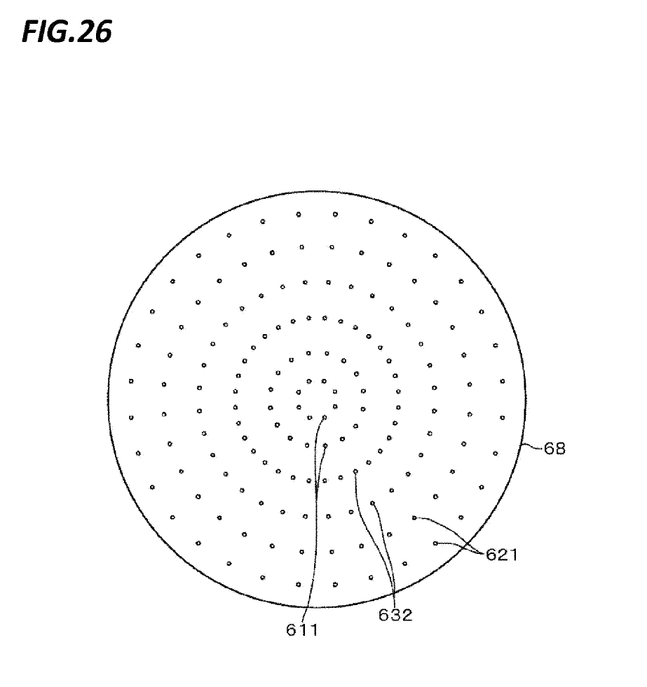

FIG. 26 is a plan view illustrating the plate 68 at the eighth tier from the top. Holes 611, holes 621, and holes 632 are formed in the plate 68 at the positions overlapping the ends of the grooves 519, the ends of the grooves 529, and the ends of the grooves 631 of the plate 67, respectively. The holes 611 are formed in the central area of the plate 68, and arranged in two rows along the circumferential direction of the plate 68. The holes 621 are formed in the circumferential edge area of the plate 68, and arranged in two rows along the circumferential direction. The holes 632 are formed in the intermediate area of the plate 68, and arranged in two rows along the circumferential direction.

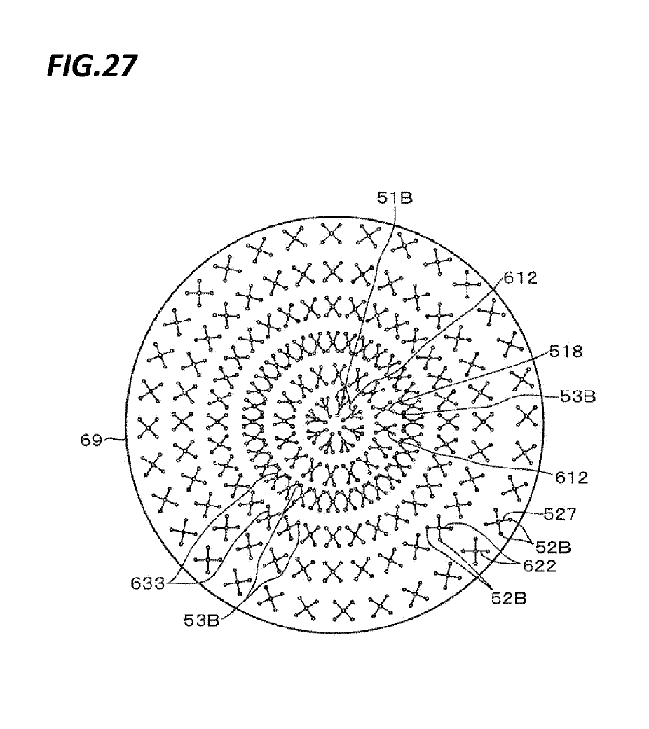

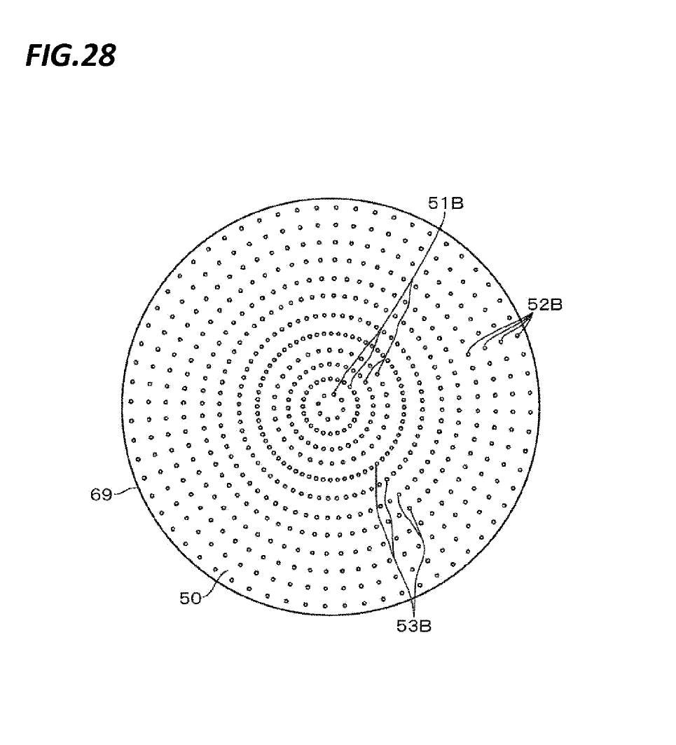

FIGS. 27 and 28 illustrate a top surface and a bottom surface of the plate 69 at the lowermost tier, respectively. The plate 69 is configured in eight-fold symmetry, and grooves 612 that form the first gas flow paths 51 are formed in two rows in the central area along the circumferential direction of the plate 69. The grooves 612 are formed to have ends diverged from the junctions in four directions, and the gas ejecting holes 51B are formed at the respective ends. The holes 611 of the plate 68 are opened at the junctions. Among the grooves 612, some at the central side of the plate 69 are formed in a bird's foot shape, so that one end is directed to the central side of the plate 69 from the junction, and other three ends are directed to the circumferential edge area side of the plate 69. Among the grooves 612, others at the circumferential edge area side of the plate 69 are formed in an X shape, so that two ends are directed to the center of the plate 69 from the junction, and other two ends are directed to the circumferential edge area side of the plate 69. The grooves 612 are formed in the same manner as each other except that they are diverged in different directions as described above.

Grooves 622 that form the second gas flow paths 52 are formed in two rows in the circumferential edge area of the plate 69 along the circumferential direction of the plate 69. The grooves 622 are formed in an X shape to have ends diverged from the junctions in four directions. Two ends of each of the grooves 622 are directed to the central side of the plate 69, and other two ends are directed to the circumferential edge area side of the plate 69. The gas ejecting holes 52B are formed at the respective ends. Also, the holes 621 of the plate 68 are opened at the junctions.

Grooves 633 that form the third gas flow paths 53 are formed in two rows in the intermediate area of the plate 69 along the circumferential direction of the plate 69. The grooves 633 are formed in the same manner as the grooves 622, and the gas ejecting holes 53B are formed at the respective ends. Also, the holes 632 of the plate 68 are opened at the junctions of the grooves 633.

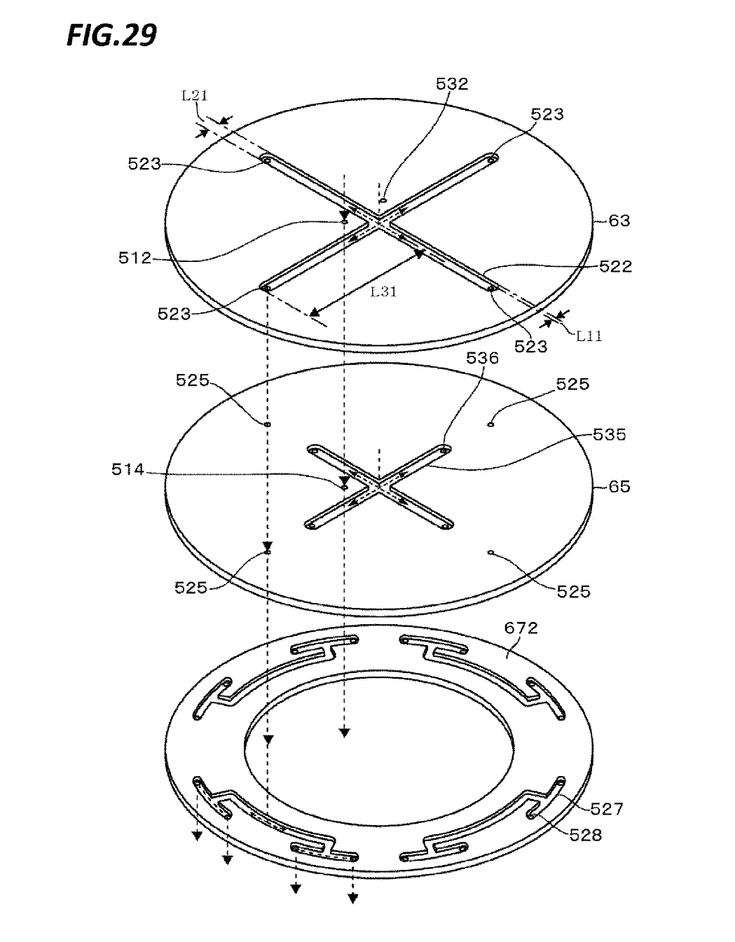

Hereinafter, gas flow paths formed in the respective plates as described above will be described. The processing gas supplied from the gas supply holes downwardly passes through the holes of the plate connected to the gas supply holes to be supplied to the junction of the radially formed grooves. Then, the processing gas horizontally spreads within the gas supply unit 5 from the junction toward the respective ends of the grooves, and flows down from the holes formed at the respective ends to be supplied to the junctions of the radially formed grooves. In this manner, the processing gas flows down while being repeatedly diffused in the horizontal direction by the grooves. That is, there are provided a group of upper tier side flow paths which include upper tier side vertical flow paths diverged from the gas supply holes and horizontal flow paths connected to the upper tier side vertical flow paths, and a group of lower side flow paths which include lower-side vertical flow paths connected to the respective horizontal flow paths of the upstream side flow paths, and horizontal flow paths connected to the lower-side vertical flow paths. Then, the processing gas which have flowed the respective groups of the flow paths is finally ejected from the gas ejecting holes. FIG. 29 illustrates a gas flow of in the plates 63, 65, and 672 by dotted-line arrows, as an example of the gas flow as described above.

Also, in the respective plates, among grooves constituting the first gas flow paths 51 to the third gas flow paths 53, grooves that form the same gas flow paths are configured to be identical to each other in groove width, length from the junction to end, and groove depth. Hereinafter, the grooves 522 of the second gas flow paths 52 of the plate 63 illustrated in FIG. 29 will be described in detail. The respective portions within the grooves 522 are configured to be identical to each other in depth L11. Also, respective portions within the grooves 522 are configured to be identical to each other in groove width L21. The grooves 522 have four diverged paths formed from the junction at the center of the cross shape due to its cross shape, but the diverged paths are configured to be identical to each other in length L31. Also, in the cross-shaped grooves 535 of the plate 65 illustrated in the same drawing, the respective portions are configured to be identical to each other in depth, width, and length from the junction to each of the four ends. In the respective plates, among the holes constituting the first gas flow paths 51 to the third gas flow paths 53, the holes that form the same gas flow paths have identical apertures. For example, the cross-shaped grooves 522 have the four holes 523 opened therein, but the apertures thereof are identical to each other. Also, the cross-shaped grooves 535 have the four holes 536 opened therein, but the aperture thereof are identical to each other.

Through the above described configuration of the grooves and the holes, the respective diverged first gas flow paths 51 extending from the gas supply hole 51A to the respective gas ejecting holes 51B are matched with each other in flow path length and flow path diameter. In the same manner, the respective diverged second gas flow paths 52 extending from the gas supply hole 52A to the respective gas ejecting holes 52B are matched with each other in flow path length and flow path diameter, and the respective diverged third gas flow paths 53 extending from the gas supply hole 53A to the respective gas ejecting holes 53B are matched with each other in flow path length and flow path diameter. The period of time for gas flowing refers to a time required until the gas supplied to the gas supply hole 51A to 53A is ejected from the gas ejecting holes 51B to 53B.

The width of each of the grooves ranges for example, from 2 mm to 4 mm, and the depth ranges, for example, from 0.3 mm to 0.9 mm. Also, the diameter of each of the holes in each plate ranges, for example, from 0.5 mm to 3.0 mm, and the diameter of each of the gas ejecting holes 51B to 53B ranges, for example, from 0.5 mm to 3.0 mm.

In the gas supply unit 5, the respective flow paths that extend from one of the gas supply holes 51A to 53A to respective gas ejecting holes formed in the gas ejecting surface 50 to be connected to the gas supply hole are configured to be matched with each other in flow path length and flow path diameter. Here, the respective flow paths do not collectively indicate the first gas flow paths 51 to the third gas flow paths 53 which are partitioned from each other, but separately indicate the respective diverged flow paths in the first gas flow paths 51, the respective diverged flow paths in the second gas flow paths 52, and the respective diverged flow paths in the third gas flow paths 53.

According to the shape of a device, or the limitation in processing, the flow path lengths in the respective flow paths are considered to be varied. In such a case, according to the variation, the flow path diameters in the respective flow paths are adjusted, so that periods of time for gas flowing from one gas supply hole to respective gas ejecting holes connected to the gas supply hole may be matched with each other as described below. For example, a flow path having a shorter flow path length than other flow paths may be set to have a smaller width (flow path diameter or cross-sectional area) than other flow paths, so that the pressure loss may be increased, and the flow velocity of a gas may be reduced. This may offset the shortened length of the flow path length, thereby allowing periods of time for gas flowing to be matched with each other.

In order to allow periods of time for gas flowing from one gas supply hole to respective gas ejecting holes connected to the gas supply hole to be matched with each other as described below, it is preferred that the respective flow paths extending from the gas supply hole to the respective gas ejecting holes are matched with each other in the flow path volume. For example, matching in flow path volume indicates that when a maximum value of flow path volumes of the gas flow paths is set to V max, and a minimum value is set to V min, (V max−V min)/V min≦50%. It is more preferable that the left side value of the equation is 30% or less, and it is further preferable that the left side value is 10% or less.

Also, in order to allow periods of time for gas flowing to be matched with each other, it is preferable that the respective flow paths extending from the gas supply hole to the respective gas ejecting holes are matched with each other in flow path length. When a maximum value of flow path lengths of the respective flow paths extending from the gas supply hole to the respective gas ejecting holes is set to Lmax, and a minimum value is set to Lmin, (Lmax−Lmin)/Lmin≦50%. It is more preferable that the left side value of the equation is 30% or less, and it is further preferable that the left side value is 10% or less.

The matching of the periods of time for gas flowing indicates that (Tmax−Tmin)/Tmin≦50% when a maximum period of time required until a gas supplied to any one of the gas supply holes 51A to 53A is ejected from the respective gas ejecting holes corresponding to the gas supply hole is set as Tmax and a minimum period of time is set as Tmin. The variation to this extent allows the effect of the present disclosure to be sufficiently achieved, and thus, a processing within each of the central area, the circumferential edge area, and the intermediate area of the wafer W to be performed with a sufficiently high uniformity. Also, it is more preferable that (Tmax−Tmin)/Tmin≦30%, and it is further more preferable that the left side value is 10% or less.

For example, the period of time for flowing in one gas ejecting hole among the plurality of gas ejecting holes that constitute one group of gas flow paths among the first gas flow paths 51 to the third gas flow paths 53 is measured in a state in which other gas ejecting holes are closed with, for example, a tape. In the same manner, the periods of time for flowing in other gas ejecting holes one by one are also sequentially measured. In this manner, the periods of time for flowing may be collected and verified for all the gas ejecting holes. In measuring the periods of time for flowing, the timing of initiating gas supply may be set to the time of issuing an ON command of a valve attached on the gas ejecting holes, and the timing of gas ejecting may be detected by providing an anemometer on the disposition unit 23.

Also, in order to achieve the object of the present disclosure, it is considered that the design is preferably made so that the periods of time for flowing may be matched with each other in the same gas ejecting holes among the gas ejecting holes 51B to 53B, if possible. However, when it is difficult to perform a processing that equalizes volumes among flow paths due to the processing precision or the structure, the mismatching among volumes in the respective flow paths may not be avoided. Even in such a case, when the above described equation is satisfied, the periods of time for flowing may be matched.

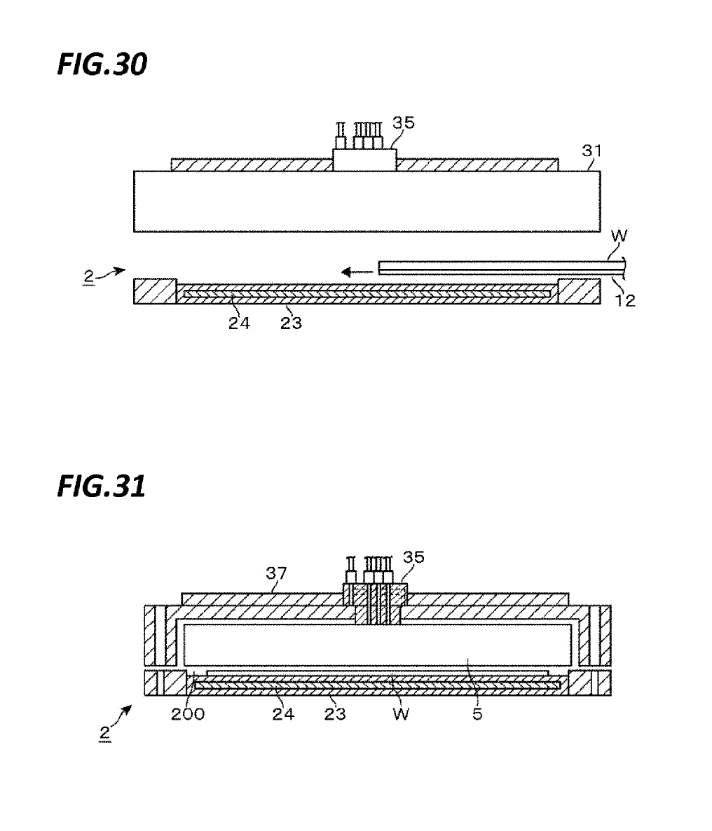

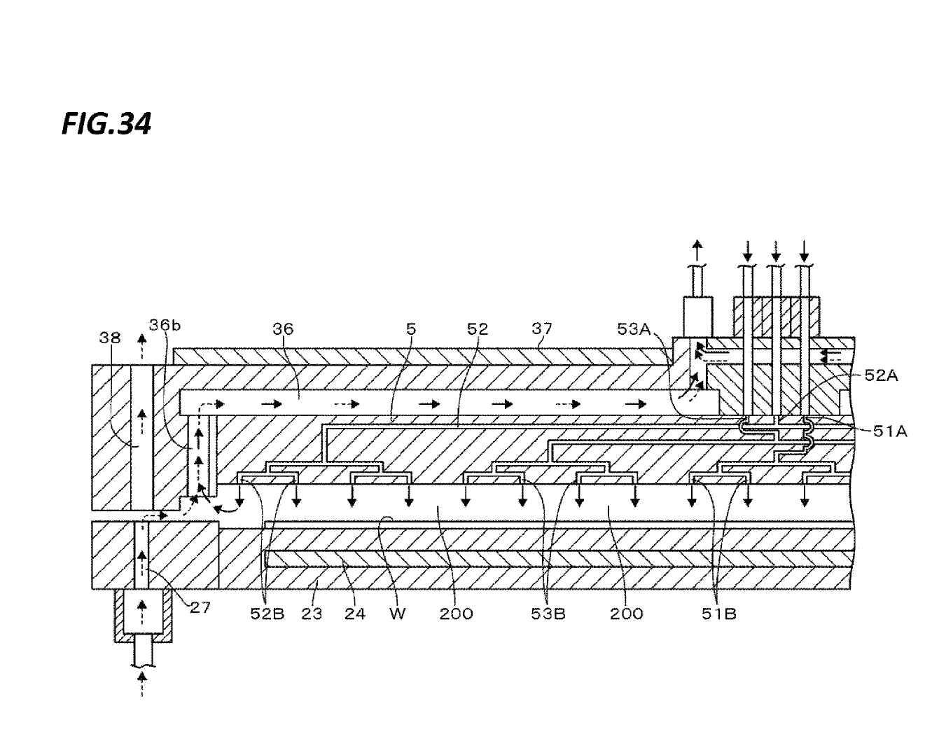

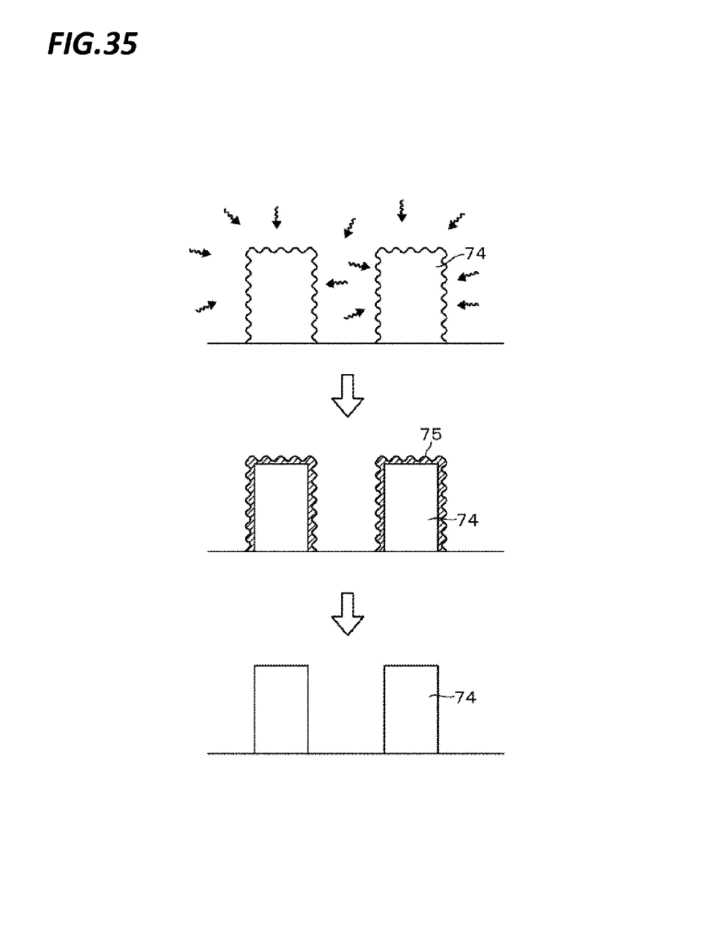

Hereinafter, the operation of the solvent supply apparatus 1 will be described with reference to FIGS. 30 to 33 illustrating the operation of the solvent supply apparatus 1 according to respective processes, FIG. 34 illustrating flows of gases indicated by arrows during processing of the wafer W, and FIG. 35 illustrating the state of a resist pattern. First, the wafer W is delivered to the plate 12 at the stand-by position illustrated in FIG. 1 by the external conveying arm (not illustrated). As illustrated in the upper part of FIG. 35, the surface of a resist pattern 74 of the wafer W is rough and is formed with irregularities. Also, inside the processing chamber 2, a processing gas atmosphere is substituted with a purge gas atmosphere after a processing of a preceding wafer W is completed. Thus, the inside of the first gas flow paths 51 to the third gas flow paths 53 of the gas supply unit 5 is placed in a state where the purge gas remains. Also, the atmosphere within the processing area 200 contains the purge gas and atmospheric air that is introduced during the carrying-out of the preceding wafer W.

As illustrated in FIG. 30, the cover 31 is moved up to the carrying-in/out position of the wafer W, and the plate 12 is moved to a position above the disposition unit 23. Next, when the pins 25 receive the wafer W by moving up, the plate 12 returns back to the stand-by position, and the pins 25 move down to dispose the wafer W on the disposition unit 23. Subsequently, as illustrated in FIG. 31, the cover 31 is moved down to the processing position to form the processing area 200. Also, the cover 31 is heated up to a temperature higher than the dew point of the solvent (e.g. 100) by the heater 37 so that the solvent gas is hardly condensed.

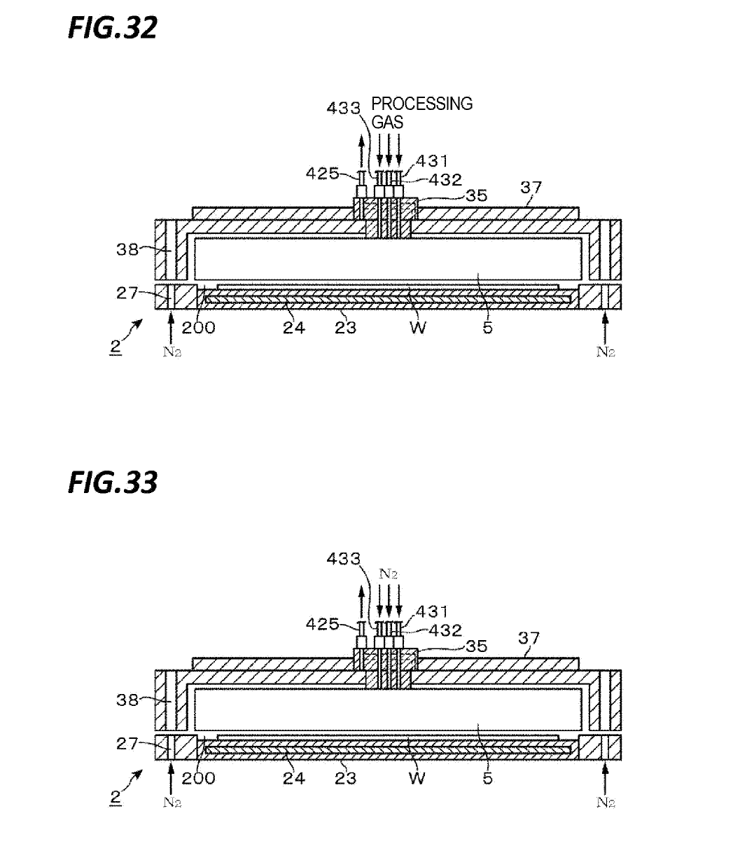

Then, as illustrated in FIG. 32, the processing gas is supplied into the processing area 200 to perform a smoothing process. In the smoothing process, the wafer W is heated up to a temperature not lower than the dew point of the solvent, for example, 80° C., by controlling the output of the heater 24 so as to allow an appropriate amount of solvent to be easily adhered to the wafer W. While the temperature control is performed in this manner, the processing gas is supplied from the gas supply tubes 431 to 433 to the gas supply holes 51A to 53A of the gas supply unit 5.

For example, since the processing gas ejected from the gas ejecting holes 51B to 53B at matched timings flows toward the exhaust holes 36b formed at the lateral side of the wafer W as illustrated in FIG. 34, the resist pattern may be further dissolved at the circumferential edge area of the wafer W than at the central area. In this example, in order to suppress such a problem and to allow the dissolution to be uniformly performed, the flow rates of the gas to be supplied to the respective gas supply holes are set in the order of 51A>53A>52A of the gas supply holes, and thus the supply flow rate of the processing gas at the central area side is set to be larger than that at the circumferential edge area side of the wafer W. While the gas supply is performed in this manner, the inside of the processing area 200 is exhausted by the exhaust tube 425, and the purge gas is supplied to the purge gas flow paths 27 and 38.

When the heating temperature of the wafer W is not higher than the dew point, e.g., 23° C., the solvent may be excessively condensed on the wafer W, thereby causing the smoothing to locally or suddenly progress. In order to avoid this phenomenon, the wafer W is heated up to a temperature not lower than the dew point of the solvent, e.g. 80° C., as described above. However, instead of such temperature control, the concentration of the solvent in the processing gas, and the flow rate of the processing gas may be reduced so as to suppress the smoothing from progressing locally and suddenly. Thus, the temperature of the wafer W may be set to a temperature not higher than the dew point to perform the processing.

FIG. 34 illustrates the flow of the processing gas indicated by the solid-line arrows, and the flow of the purge gas indicated by the dotted-line arrows, respectively. In the gas supply unit 5, the processing gas supplied from the gas supply holes 51A, 52A, and 53A flows to the downstream side by diffusing in the first gas flow paths 51 to the third gas flow paths 53 diverged in a stepwise shape as described above. Since the purge gas remains within the first gas flow paths 51 to the third gas flow paths 53, the purge gas is ejected first and then the processing gas is ejected from the gas ejecting holes 51B to 53B.

Here, since the first gas flow paths 51 to the third gas flow paths 53 are configured to match the periods of time for gas flowing from the gas supply hole to the respective gas ejecting holes in the same gas flow paths, the periods of time until the processing gas is substituted for the atmosphere (the purge gas) within the flow paths from the gas supply hole to the respective gas ejecting holes are matched with each other in the same gas flow paths (gas flow paths sharing the gas supply hole) among the first gas flow paths 51 to the third gas flow paths 53. Here, since the gas within the same gas flow paths is ejected from the respective gas ejecting holes in a state where the ejecting timings and rates are matched, the purge gas remaining within the flow paths is forced out by the processing gas at the matched timings from the respective gas ejecting holes that constitute the corresponding gas flow paths. In this manner, the timing when the processing gas reaches the respective gas ejecting holes immediately after initiating the ejection of the processing gas is matched in the same gas flow paths among the first gas flow paths 51 to the third gas flow paths 53.

The flow rates of the processing gas to be supplied to the first gas flow paths 51 to the third gas flow paths 53 are separately controlled, and the respective flow rates are set so that variation of a gas concentration of the processing gas may be suppressed in a range from the circumferential edge area to the central area of the wafer W. When the resist pattern 74 is exposed to the processing gas in this manner to collide with solvent molecules, an outer layer portion 75 of the resist pattern 74 is swelled by absorbing the solvent, and the resist film in the corresponding portion is softened and dissolved as illustrated in the intermediate part of FIG. 35. Thus, the resist polymer flows. Therefore, only the fine irregularities on the pattern mask surface are planarized, thereby improving the roughness of the surface of the resist pattern 74 as illustrated in the lower part of FIG. 35.

The processing gas supplied into the processing area 200 is exhausted by the exhaust passage 36 via the exhaust holes 36b which are formed to surround the wafer W at the lateral side of the wafer W. Also, the inside of the processing area 200 is in a negative pressure state due to a difference between the supply flow rate of the processing gas and the exhaust rate. Thus, a part of the purge gas is drawn into the processing area 200, and is exhausted, together with the processing gas, via the exhaust passage 36. Thus, there exists an air curtain of the purge gas at the outside of the processing area 200. This also suppresses the leakage of the processing gas to the outside of the processing chamber 2.

Subsequently, as illustrated in FIG. 33, the supply of the processing gas is stopped and the supply of the purge gas to the gas supply unit 5 is initiated. Then, after the inside of the processing area 200 is substituted by the purge gas, the supply of the purge gas is stopped and the exhaustion of the inside of the processing area 200 is stopped. The cover 31 is moved up to the carrying-in/out position, and the wafer W is delivered to the plate 12 by the co-operation of the pins 25 and the plate 12. The wafer W is carried out to the outside of the solvent supply apparatus 1 by an external conveying arm.

In the above described solvent supply apparatus 1, when initiating a processing, the purge gas is substituted by the processing gas in the inside of the first gas flow paths 51 of the gas supply unit 5. However, as described above, the timing when the processing gas reaches the respective gas ejecting holes immediately after initiating the ejection of the processing gas is matched in one group of gas flow paths among the first gas flow paths 51 to the third gas flow paths 53. That is, the processing gas is supplied with high uniformity to the central area of the wafer W where the gas ejecting holes 51B of the first gas flow paths 51 are opened, to the circumferential edge area of the wafer W where the gas ejecting holes 52B of the second gas flow paths 52 are opened, and to the intermediate area of the wafer W where the gas ejecting holes 53B of the third gas flow paths 53 are opened, respectively. Then, in this way, so to speak, the groups of the first gas flow paths 51 to the third gas flow paths 53 are partitioned from each other, and the flow rates of the gas to be supplied to the first gas flow paths 51 to the third gas flow paths 53 may be separately controlled. Thus, in the central area, the circumferential edge area and the intermediate area of the wafer W, the concentration of the processing gas may be easily controlled with high precision. Accordingly, the variation of the gas concentration may be suppressed over the entire surface of the wafer W, and as a result, the roughness of the surface of the resist pattern may be improved with a high uniformity over the entire in-plane.

Also, in the gas supply unit 5, since the volume of the space through which the gas flows is very small, the period of time when the gas passes through the inside of the gas supply unit 5 is shortened, and the supply of the gas into the processing area 200 may be quickly performed. Thus, the smoothing process may be quickly initiated, and also the substitution with the purge gas may be performed within a short time.

In the solvent supply apparatus 1, the heater 37 provided in the cover 31 and the heaters 451 to 453 provided in the gas supply tubes 431 to 433 suppress the solvent from being condensed within the processing chamber 2. By suppressing the solvent from being condensed, the solvent as a liquid is suppressed from being dropped on the wafer W, and the concentration of the processing gas is suppressed from being varied on the surface of the wafer W. Accordingly, it is assured that the deterioration of the in-plane processing uniformity of the wafer may be suppressed.

When the processing gas atmosphere within the processing area 200 is substituted with the purge gas atmosphere, the processing gas is gradually diluted with the purge gas within the processing area 200. At this time, the period of time until the processing gas within the flow paths from the gas supply hole to the respective gas ejecting holes is substituted by the purge gas is matched in the same gas flow paths among the first gas flow paths 51 to the third gas flow paths 53. Thus, the timing when the purge gas reaches the respective gas ejecting holes immediately after initiating the ejection of the purge gas is matched in the same gas flow paths. This makes the dilution extents of the processing gas uniform with the purge gas in the central area, in the intermediate area, and the circumferential edge area, respectively. That is, the flow rates of the purge gas to be supplied to the first gas flow paths 51 to the third gas flow paths 53 may be appropriately set, respectively. Thus, during the substitution of the purge gas for the inside of the processing area 200, the concentrations of the processing gas may be controlled in the respective areas of the wafer W so as to allow uniform processing to be performed on the surface of the wafer W. In order to achieve such uniform processing, the flow rates of the purge gas to be supplied to the first gas flow paths 51 to the third gas flow paths 53, respectively may be set to be identical or different in the same manner as in the processing gas.

The solvent supply apparatus 1, together with a LWR test device configured to inspect a smoothing result, may be incorporated in, for example, a coating/developing device provided with a coating unit configured to perform coating of the resist, or a developing unit configured to perform developing processing. Then, there is an advantage in that based on the result of the test by the test device, when there occurs a requirement for controlling the extent of progress in the smoothing process on the wafer surface, a countermeasure may be quickly performed by controlling the amounts of the gas to be supplied to the respective gas flow paths as described above. The case where a requirement for control on the wafer surface occurs refers to, for example, a case where the in-plane processing uniformity of the wafer W is varied by variation in the kind of the resist to be coated on the wafer W, or the dimension of the resist pattern.

In order to achieve in-plane processing uniformity of the wafer W, the ratio of the solvent gas in the processing gas may be controlled instead of the flow rates of the processing gas to the respective gas supply holes. Specifically, for example, the vaporization tank 441 configured to perform bubbling is connected to each of the gas supply tubes 431 to 433, and a line configured to supply N2 gas as a dilution gas to each of the gas supply tubes 431 to 433 is connected at the downstream side of the vaporization tank 441. Then, the amount of the solvent vaporized by bubbling, and the flow rate of the dilution gas may be appropriately controlled.

The timings when the processing gas is supplied to the first gas flow paths 51 to the third gas flow paths 53 may be different among the gas flow paths. For example, the processing gas may be sequentially supplied to the first gas flow paths 51, the third gas flow paths 53, and then the second gas flow paths 52. Then, the supply of the processing gas into the first gas flow paths 51 to the third gas flow paths 53 is stopped at once. By controlling the timings of gas supply in this manner, the solvent concentration on the surface of the wafer W may be controlled, and the in-plane processing uniformity of the wafer W may be improved.

### Second Exemplary Embodiment

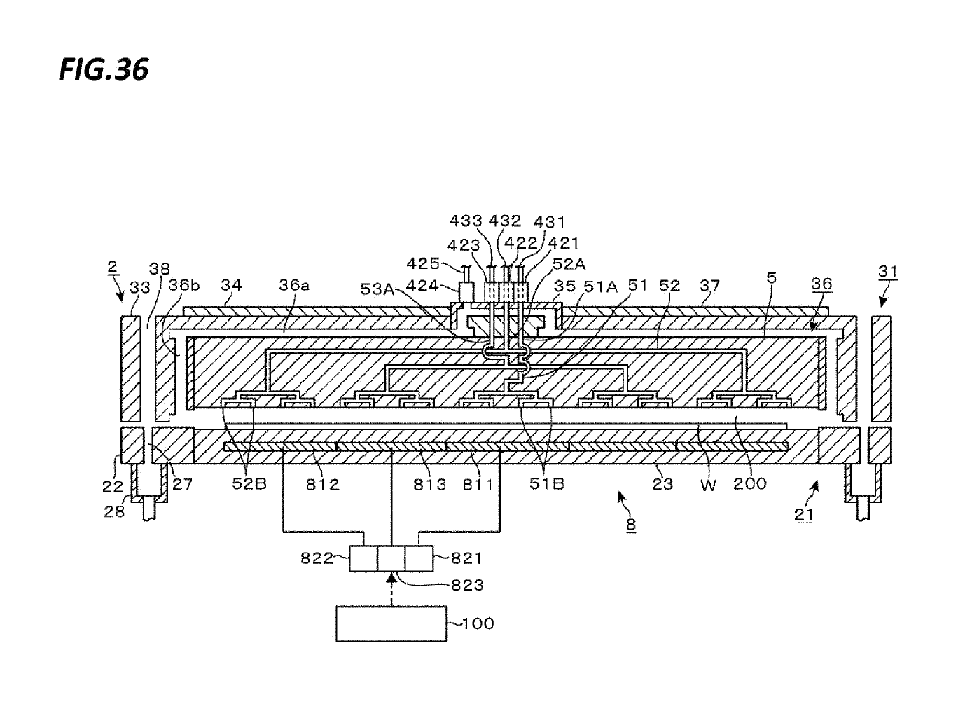

FIG. 36 illustrates a solvent supply apparatus 8. The solvent supply apparatus 8 is different from the solvent supply apparatus 1 in that instead of the heater 24, heaters 811 to 813 are provided along the radial direction of the wafer W. The heater 811 is provided below the central area of the wafer W. The heater 812 is provided below the circumferential edge area of the wafer W to surround the heater 813, and the heater 813 is provided below the intermediate area of the wafer W to surround the heater 811. The heaters 811 to 813 are connected to power supply units 821 to 823, respectively, and power to be supplied to the heaters 811 to 813 is individually controlled based on commands from the control unit 100. Accordingly, the temperature of the central area, the intermediate area, and the circumferential edge area of the wafer W may be individually controlled.

When the temperature of the wafer is high, the solvent adsorbed on the wafer may be easily evaporated, thereby reducing the amount of the solvent adsorbed on the wafer surface. Meanwhile, when the temperature of the wafer is low, a period of time when the solvent adsorbed on the wafer stays is prolonged, thereby increasing the amount of the solvent adsorbed on the wafer surface. That is, in the solvent supply apparatus 8, since the adsorption amount of the solvent is adjusted in each area by individually controlling the temperature of the wafer surface in each area, it is possible to further improve the in-plane processing uniformity of the wafer W.

For example, a test wafer is subjected to a smoothing process, and its LWR is measured. Based on the measurement result, the temperature of the heaters 811 to 813 when performing a smoothing process on a product wafer is controlled. For example, since the processing gas flows toward the exhaust holes 36b as described above, the resist pattern may be further dissolved at the circumferential edge area of the wafer W than at the central area. When the smoothing may be more easily performed at the circumferential edge area than at the central area, as described above, the outputs of the heaters 811 to 813 are controlled so that the temperature at the central area side of the wafer W may be lower than that at the circumferential edge area side at the time of supplying the processing gas into the processing area 200. Accordingly, when the processing is performed, the adsorption amount of the solvent gas at the central area side of the wafer W is increased, and thus the extents of progress in smoothing on the wafer surface are matched.

Also, for example, the processing may be more easily performed at the central area side of the wafer W than at the circumferential edge area side according to the kind or supply amount of the solvent, or the exhaust rate of the processing area 200. In this case, the outputs of the heaters 811 to 813 are controlled so that the temperature at the circumferential edge area side of the wafer W may be lower than that at the central area side. Accordingly, the adsorption amount of the solvent gas at the circumferential edge area side is increased. In the same manner as in the solvent supply apparatus 1, the solvent supply apparatus 8 may be incorporated in a coating/developing device together with an LWR test device. When there occurs a requirement for controlling the extent of progress in the smoothing process on the wafer surface, the outputs of the respective heaters are controlled based on the result of the test. Accordingly, when the following wafer W that is carried into the solvent supply apparatus 8 after the test is processed, the in-plane processing uniformity of the wafer W may be quickly improved.

Subsequently, an example of controlling the temperature of the wafer in the smoothing process will be described.

(Temperature Control Example 1)

In the smoothing process, until a predetermined time is elapsed after initiating the supply of the processing gas into the processing area 200, the wafer W is heated up to a temperature not lower than the dew point of the solvent gas (e.g. 100° C.) by the heaters 24, or 811 to 813. Then, after the predetermined time is elapsed after initiating the supply of the processing gas into the processing area 200, a temperature control is performed to cool the wafer W to, for example, 80° C. In this case, when the temperature of the wafer W is relatively high (e.g., 100° C.), the smoothing process is hardly progressed. Then, while the wafer W is cooled, the solvent gas is adsorbed on the surface of the wafer W, thereby allowing the smoothing process to be progressed.

Immediately after the supply of the processing gas into the processing area 200 is initiated, the purge gas or the atmospheric air exists within the processing area 200 as described above. Thus, the concentration of the processing gas is low. Then, when the processing gas is continuously supplied into the processing area 200, the concentration of the processing gas is gradually increased. Accordingly, for some time after initiating the supply of the processing gas into the processing area 200, the concentration of the processing gas within the processing area 200 is hardly stabilized. For this reason, for example, the timing when the inside of the processing area 200 is substituted with the processing gas may be grasped, and the temperature of the wafer W may be controlled so as to progress the smoothing process at the timing. Then, the smoothing process may be performed in a state where the entire surface of the wafer is in contact with the processing gas at the stabilized concentration. As described above, through the control of the temperature as well as the control of the gas flow rates, the processing uniformity may be further improved.

(Temperature Control Example 2)

In the smoothing process, the temperature of the wafer W at the time of stopping the smoothing reaction is controlled to be higher than that at the time of performing the smoothing process. When the solvent is adsorbed on the resist pattern, the flowability of the resist is increased just before the surface is dissolved. Then, the planarization of roughness of the surface is rapidly progressed. Thus, when the smoothing is progressed as it stands, dissolution of the resist is excessively progressed, thereby collapsing the pattern shape. Accordingly, it is desirable to stop the smoothing process at the timing when the roughness of the surface of the resist pattern is improved. For example, after the timing when the resist pattern is dissolved is grasped, the wafer W may be heated at a temperature higher by 20° C. than the temperature for performing the smoothing process, for example, at a timing that is 2 to 10 seconds ahead of the grasped timing. In this manner, when the heating temperature of the wafer W is increased at the above described timing, the solvent gas is hardly attached on the wafer W, and the solvent is easily evaporated. As a result, the smoothing process is stopped, and thus the dissolution of the resist pattern may be stopped at the timing when the roughness of the surface of the resist pattern is improved.

In this case, the temperature control of the wafer W may be performed by the heaters 24 or 811 to 813, or a purge gas at a relatively high temperature (e.g. 100° C.) may be supplied into the processing area 200 so as to increase the temperature of the wafer W. In a configuration where the high temperature purge gas is supplied to the processing area 200, until the processing area 200 is completely substituted with the purge gas, the processing gas exists within the processing area 200 and thus the smoothing process is in progress. Accordingly, when at the above described timing, the supply of the processing gas is stopped, and the high temperature purge gas is supplied, the smoothing process may be stopped, and the atmosphere within the processing area 200 may be substituted with the purge gas.

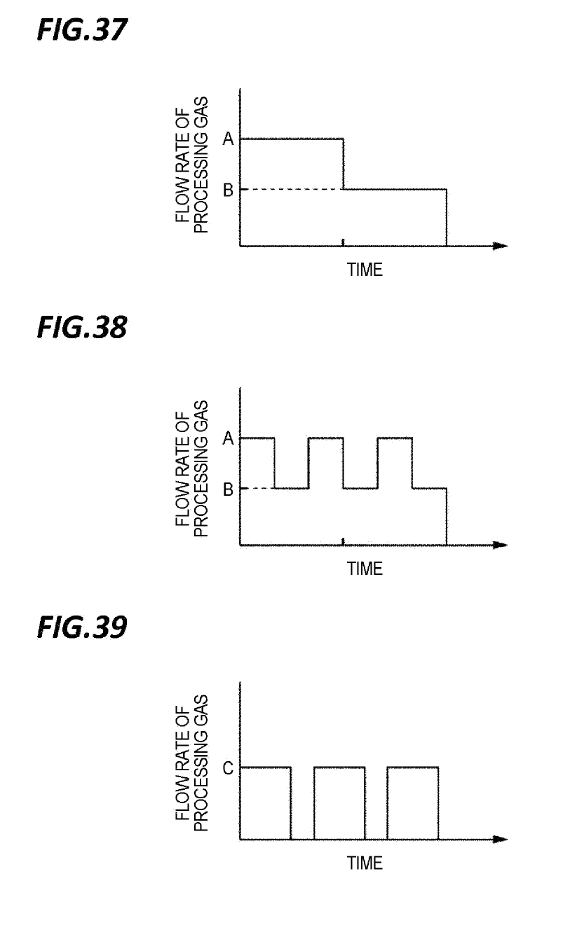

Also, in the solvent supply apparatus 1 or 8, as illustrated in FIGS. 37 to 39, the supply amount of the processing gas may be controlled. In the example illustrated in FIG. 37, the supply amount of the processing gas from the first gas flow paths 51 to the third gas flow paths 53, respectively, is changed during the processing. For example, the processing gas is supplied at A L/min in the first half of a processing step, and supplied at B L/min in the latter half. Also, the example illustrated in FIG. 37 is a control example in which a step of supplying the processing gas at A L/min and a step of supplying the processing gas at B L/min are alternately repeated. In the example illustrated in FIG. 39, a step of supplying the processing gas at C L/min is repeatedly performed intermittently.

As described above, in the smoothing, there is a timing when planarization of the roughness of the surface is rapidly progressed. Thus, when the smoothing reaction is excessively quickly progressed, it is difficult to determine the time of stopping the smoothing reaction. When the supply flow rate of the processing gas is controlled in this manner, a period of time when the smoothing is highly progressed and a period of time when the smoothing is slightly progressed may exist among smoothing processes. Thus, it is easy to determine the time of stopping the smoothing reaction, and the smoothing reaction may be stopped at the optimized timing. Accordingly, it is possible to improve the roughness of the surface of the resist pattern with a high in-plane processing uniformity. When the control of the supply of the processing gas is performed as illustrated in FIGS. 37 to 39, the flow rates of the processing gas from the first gas flow paths 51 to the third gas flow paths 53, respectively, may be same or different. Further, instead of the flow rate of the processing gas, the concentration of the solvent in the processing gas may be varied according to the patterns in the drawings.

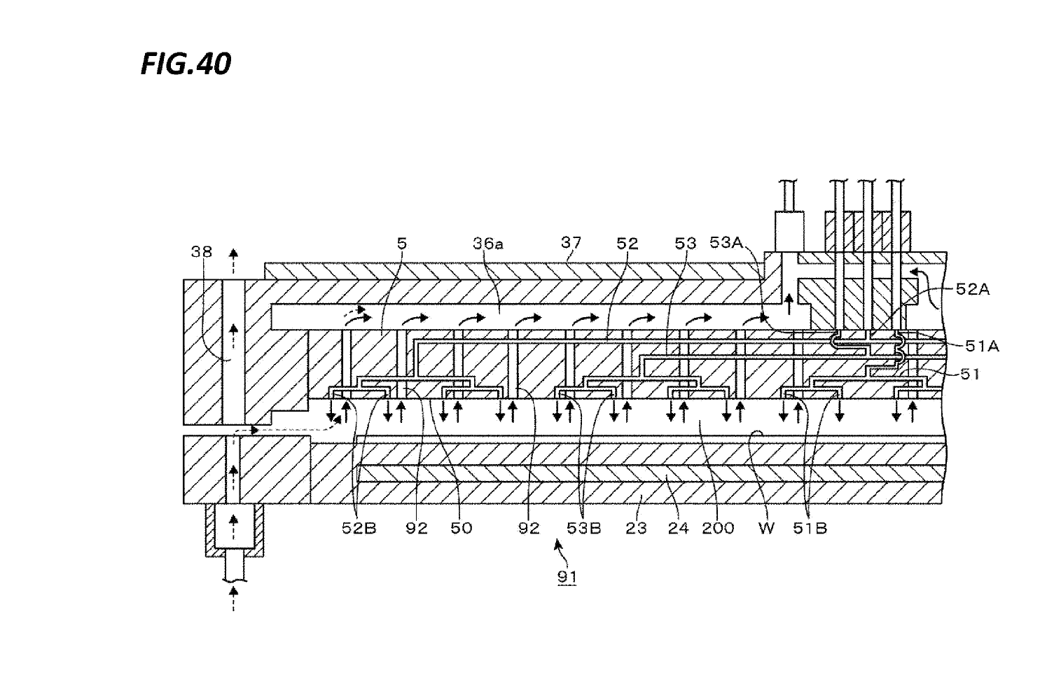

FIG. 40 illustrates a further configuration example of a processing chamber. A processing chamber 91 in FIG. 40 is different from the processing chamber 2 in that the exhaust holes 36b are not formed and exhaustion is not performed at outer periphery side of the wafer W. Instead, one ends of exhaust holes 92 are formed at the gas ejecting surface 50 of the gas supply unit 5, and the other ends of the exhaust holes 92 are opened at the exhaust space 36a toward the upper side of the gas supply unit 5. The plurality of exhaust holes 92 are distributed in the surface direction of the gas supply unit 5 so as not to interfere with the first gas flow paths 51 to the third gas flow paths 53. FIG. 40 illustrates the flow of the processing gas indicated by the solid-line arrows, and the flow of the purge gas indicated by the dotted-line arrows, respectively, in the same manner as in FIG. 34. The processing gas ejected to the processing area 200 is exhausted from the exhaust holes 92 close to the gas ejecting holes from which the processing gas is ejected. Accordingly, the occurrence of an air flow toward the circumferential edge area from the central area of the wafer W is suppressed as the gas is exhausted through the exhaust holes 36b in the solvent supply apparatus 1. This suppresses the concern that the gas concentration at the circumferential edge area side of the wafer W becomes higher than that at the central area side of the wafer W on the wafer surface, and thus the uniformity of a gas concentration on the wafer surface is further enhanced. Such a configuration of the processing chamber 91 may be employed in other exemplary embodiments.

The solvent supply apparatus 1 is not limited to the use for processing of a circular substrate, but may be employed in processing of a square shape substrate. Also, the present disclosure is not limited to partition of a gas supply passage so as to individually supply a gas to the circumferential edge area side and the central area side of a substrate. For example, one half of the substrate may be treated with a processing gas from some gas flow paths, and the other half may be treated with a processing gas from other gas flow paths. Also, the present disclosure is not limited to the formation of a horizontal flow path of the gas supply unit 5 by a groove formed on a plate, but the horizontal flow path may be formed by a slit penetrating the plate in the thickness direction. That is, one plate formed with the slit may be interposed between other plates at the top and bottom sides so as to form the horizontal flow path. Also, the present disclosure may be employed in a substrate processing apparatus configured to perform a processing of a substrate by supplying a processing gas under normal pressure atmosphere, such as, for example, an atmospheric CVD apparatus, a hydrophobic processing apparatus, and an atmospheric etching apparatus. Also, the normal pressure atmosphere in the present disclosure includes a state of a reduced pressure slightly lower than a normal pressure atmosphere.

Also, it is not necessary to directly supply the purge gas that substitutes for the atmosphere of the processing area 200 to the gas supply unit 5. For example, the processing gas within the processing area 200 and the processing gas of the gas supply unit 5 may be removed by stopping the supply of the processing gas to the processing area 200, and exhausting the inside of the processing area 200 by the exhaust mechanism 426, and then the purge gas may be supplied into the processing area 200 from gas supply holes provided in, for example, the disposition unit 23 without passing through the gas supply unit 5. Accordingly, the purge gas may gradually fill the inside of the processing area 200 and the first gas flow paths 51 to the third gas flow paths 53, thereby substituting for the atmosphere of the processing area 200 and the first gas flow paths 51 to the third gas flow paths 53.

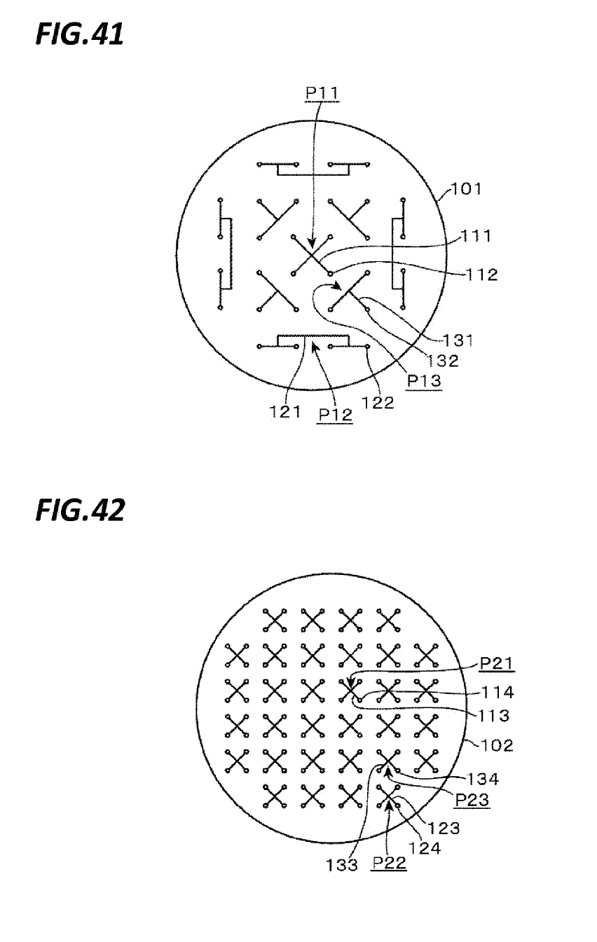

The pattern that forms the flow paths is not limited to the above described example. FIGS. 41, 42, and 43 illustrate top surfaces of plates 101, 102, and 103, and as illustrated in FIG. 44, these plates are stacked at the bottom of the plates 61 to 66 in the order of the plate 101, the plate 102, and the plate 103 from top. Cross-shaped grooves 111 are formed at the center of the top surface of the plate 101, which have holes 112 formed at ends thereof. In the drawing, at the junction indicated by P11, at the center of the grooves 111, a gas is supplied through the plates 61 to 66 from the gas supply hole 51A. Grooves 121 are formed at the circumferential edge area of the plate 101 to extend in a straight line, in which both ends of the straight line are bent at right angles toward the circumferential edge side of the plate 101, and one of the bent ends is diverged into two branches bent perpendicularly thereto. Holes 122 are formed at the ends of the grooves 121. In the drawing, the reference numeral P12 indicates the center of portions extending linearly from the grooves 121, at which a gas is supplied through the plates 61 to 66 from the gas supply hole 52A.

Also, four T-shaped grooves 131 are formed on the top surface of the plate 101 to surround the grooves 111, which have holes 132 formed at ends thereof. In the drawing, at the junction indicated by the reference numeral P13, at the center of the grooves 131, a gas is supplied through the plates 61 to 66 from the gas supply hole 53A.

A plurality of cross-shaped grooves are formed on the top surface of the plate 102. The grooves at the central area of the plate 102 are indicated by the reference numeral 113, the grooves at the circumferential edge area are indicated by the reference numeral 123, and the grooves at the intermediate area are indicated by the reference numeral 133. The holes formed at the ends of the grooves 113, 123, and 133 are indicated by the reference numerals 114, 124, and 134, respectively. The junctions at the centers of the grooves 113, 123, and 133 are indicated by the reference numerals P21, P22, and P23, respectively, and the holes 112, 122, and 132 of the plate 101 are opened at the junctions P21, P22, and P23, respectively.

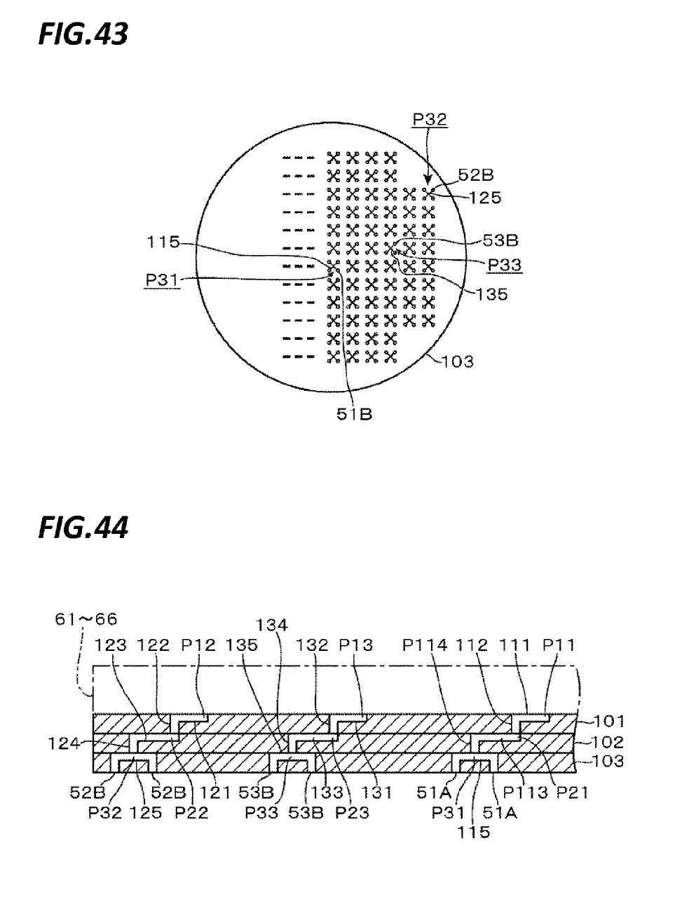

A plurality of cross-shaped grooves are formed on the top surface of the plate 103. In the drawing, the grooves at the central area of the plate 103 are indicated by the reference numeral 115, the grooves at the circumferential edge area are indicated by the reference numeral 125, and the grooves at the intermediate area are indicated by the reference numeral 135. The gas ejecting holes 51B, 52B, and 53B are formed at the ends of the grooves 115, 125, and 135, respectively. In FIG. 43, the illustration on grooves and ejecting holes of the half surface of the plate 103 is omitted. The junctions at the centers of the grooves 115, 125, and 135 are indicated by the reference numerals P31, P32, and P33, respectively, and the holes 114, 124, and 134 of the plate 102 are opened at the junctions of P31, P32 and P33, respectively.

When the plates 101 to 103 are used, the grooves 111, 113 and 115, and the holes 112 and 114 form the first gas flow paths 51, the grooves 121, 123, and 125, and the holes 122, and 124 form the second gas flow paths 52, and the grooves 131, 133, and 135, and the holes 132 and 134 form the third gas flow paths 53. The respective portions in the same grooves are identical to each other in a width, and a depth. Also, the grooves of each plate are identical to each other in a length from the junction to the holes at the respective ends of the grooves. By this, periods of time for gas flowing from a gas supply hole to respective gas ejecting holes may be matched with each other within the same gas flow paths in the same manner as in the plates 61 to 69.

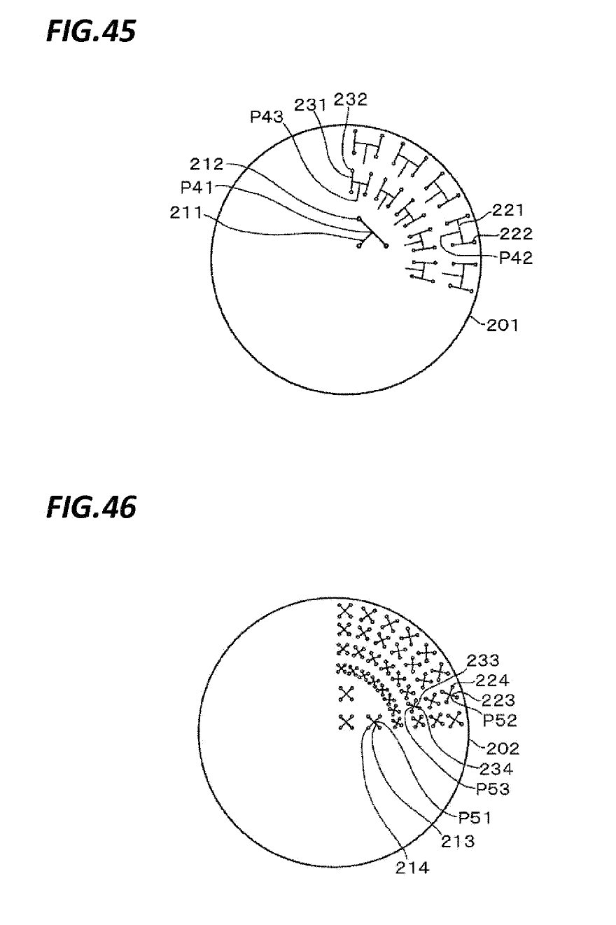

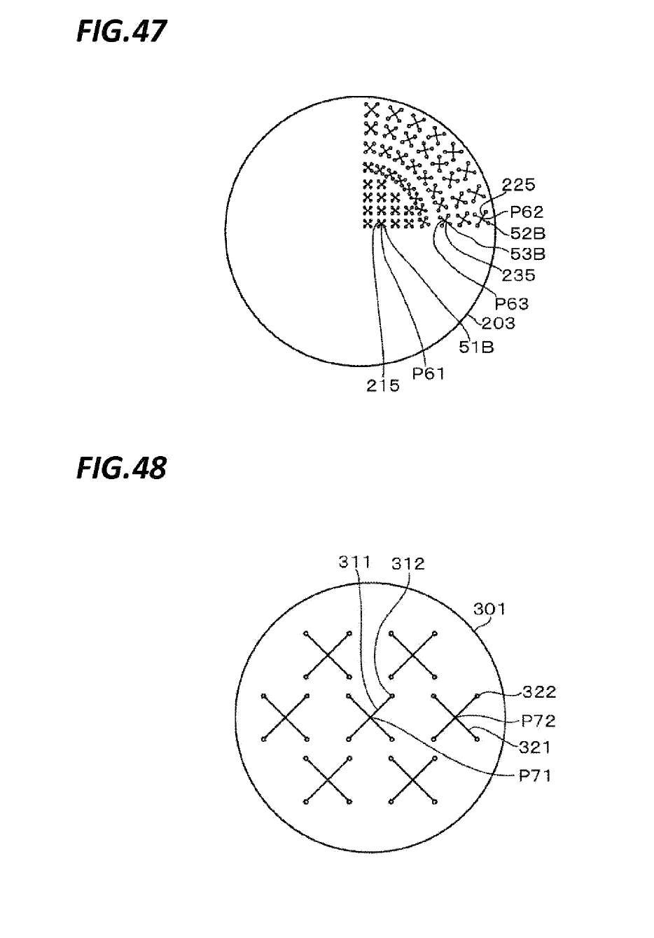

FIGS. 45 to 47 illustrates an example of another pattern formed by plates at the lower side of the gas supply unit 5. FIGS. 45 to 47 illustrate top surfaces of plates 201 to 203, and the plate 201, the plate 202, and the plate 203 are stacked in this order from top. At the top of the plates 201, 202 and 203, for example, a plurality of the same plates as the plates 61 to 66 are stacked, but the number of branches of the grooves and the number of the stacked plates are changed from those of the configuration example as above to correspond to the number of the respective grooves of the plate 201. Also, in FIGS. 45 to 47, the plates 201 to 203 are formed in rotational symmetry. Thus, for convenience of illustration, only the pattern in the region of ¼ of the plate is illustrated, but the same pattern as that in the ¼ region is also formed in the other region of ¾.

A plurality of T-shaped grooves 211 that form the first gas flow paths 51 are formed at the central area on the top surface of the plate 201. In the drawing, the reference numeral P41 indicates the junction of the grooves, which is a point to which a gas is supplied from the plate at the upper side. Holes 212 are formed at the diverged ends of the grooves 211. A plurality of grooves 221 that form the second gas flow paths 52 are formed at the circumferential edge area on the top surface of the plate 201. In the drawing, the reference numeral P42 indicates a point in the grooves 221 to which a gas is supplied from the plate at the upper side. The grooves 221 have branches diverged in the circumferential direction from P42 toward the circumferential edge area of the plate 201. Each of the diverged ends is diverged to the central area side of the plate, and the circumferential edge area side, respectively. That is, when viewed from P42, the grooves 221 have four diverged ends, and holes 222 are formed at the corresponding ends. A plurality of grooves 231 that form the third gas flow paths 53 are formed at the intermediate area on the top surface of the plate 201. The grooves 231 are formed in the same shape as that of the grooves 221 except that the size is different from that of the grooves 221. In the drawing, the reference numeral P43 indicates a point in the grooves 231 to which a gas is supplied from the plate at the upper side, and the reference numeral 232 indicates holes formed at ends of the grooves 231.

A plurality of cross-shaped grooves are formed on the top surface of the plate 202. In the drawing, the grooves at the central area of the plate 202 are indicated by the reference numeral 213, the grooves at the circumferential edge area are indicated by the reference numeral 223, and the grooves at the intermediate area are indicated by the reference numeral 233. Holes 214, holes 224, and holes 234 are formed at the ends of the grooves 213, the grooves 223, and the grooves 233, respectively. The reference numerals P51, P52, and P53 at the cross-centers of the grooves, respectively, overlap the holes 212, the holes 222, and the holes 232 of the plate 201.

A plurality of cross-shaped grooves are formed on the top surface of the plate 203. In the drawing, the grooves at the central area of the plate 203 are indicated by the reference numeral 215, the grooves at the circumferential edge area are indicated by the reference numeral 225, and the grooves at the intermediate area are indicated by the reference numeral 235. The gas ejecting holes 51B, 52B, and 53B are provided at the ends of the grooves 215, 225, and 235, respectively. The reference numerals P61, P62, and P63 at the cross-centers of the grooves, respectively, overlap the holes 214, the holes 224, and the holes 234 of the plate 202.

In these plates 201, 202, and 203, the grooves are identical to each other in a distance from the point P to which a gas is supplied from the plate at the upper side, to holes formed at the respective ends of the grooves diverged from the point P. Thus, in the same manner as other examples, periods of time for gas flowing from a gas supply hole to respective gas ejecting holes may be matched with each other within the same gas flow paths.

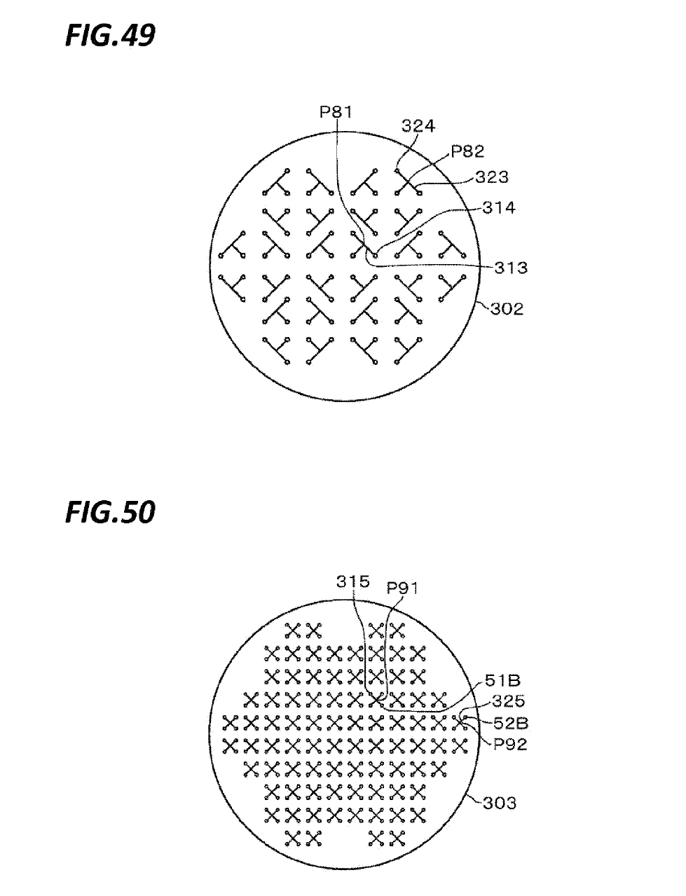

In the above described examples, three groups of gas flow paths are provided, in which each group is provided with a plurality of ejecting holes from which a gas supplied from the common gas supply hole is ejected. However, the number of groups of the gas flow paths is not limited to three, as long as a plurality of groups are formed. FIGS. 48 to 50 illustrate top surfaces of plates 301, 302, and 303, and these plates form the first gas flow paths 51 and the second gas flow paths 52. The plate 301, the plate 302, and the plate 303 are stacked in this order from top. At the top of the plates 301 to 303, the same plates as the plates 61 to 66 are provided, but unlike the above described exemplary embodiments, grooves and holes that constitute the third gas flow paths 53 are not formed. To correspond to the number of the grooves of the plate 301, in the plate 63, the number of the diverged branches of the grooves 522 that form the second gas flow paths 52 is 6.

Cross-shaped grooves 311 and 321 are formed at the central area, and the circumferential edge area on the top of the plate 301. The grooves 311 and 321 constitute the first gas flow paths 51, and the second gas flow paths 52, respectively, and to respective centers P71 and, P72, a gas is supplied from the plate at the upper side. holes at the respective ends of the grooves 311, and holes at the respective ends of the grooves 321 are indicated by the reference numerals 312 and 322, respectively. T-shaped grooves 313, and 323 are formed at the central area and the circumferential edge area, respectively, on the top of the plate 302. Junctions P81, and P82 of the grooves 313 and 323 overlap the holes 312, and 322 of the plate 301. Holes 314 and 324 are formed at diverged ends of the grooves 313 and 323, respectively. Cross-shaped grooves 315 and 325 are formed at the central area and the circumferential edge area, respectively, on the top of the plate 303. Junctions P91 and P92 of the grooves 315 and 325 overlap the holes 314 and 324 of the plate 302. The gas ejecting holes 51B and 52B are formed at the ends of the grooves 315 and 325, respectively.

[Reference Test]

Subsequently, a reference test that was performed in relation to the present disclosure will be described. In a plurality of positions along the radial direction in a wafer W (referred to as wafer A1) formed with a resist pattern, a difference between maximum width and minimum width of the pattern was measured as an LWR of a measurement value of the resist pattern. The processing on the wafer A1 was performed using a device provided with a solvent storage unit that faces the wafer W, instead of the gas supply unit 5 in the apparatus according to the exemplary embodiments as described above. By heating the storage unit, the solvent stored in the storage unit is vaporized to be supplied to the wafer W. Also, a wafer A2 that was formed with a resist pattern in the same manner as in the wafer A1 was prepared. The wafer A2 was processed using almost the same apparatus as the solvent supply apparatus 1, and then was measured in the same manner as in the wafer A1. Here, in the gas supply unit of the apparatus, gas ejecting holes formed to be diverged from one gas supply hole are formed over the range from the central area to the circumferential edge area of the wafer W, and periods of time when a processing gas introduced from a gas supply hole flows to reach respective gas ejecting holes are matched with each other.

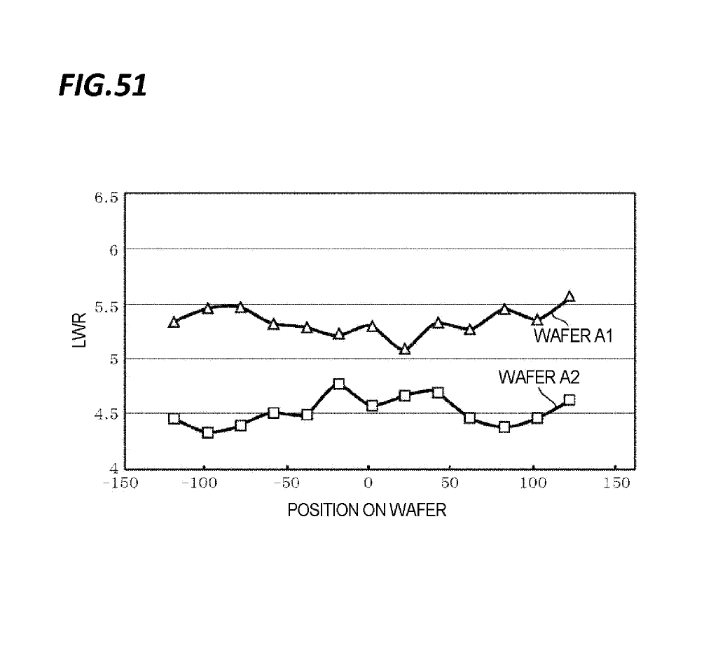

In the graph in FIG. 51, the reference test results are indicated by in the wafer A1, and □ in the wafer A2, respectively. The horizontal axis indicates measurement positions at the wafer W, in which in the horizontal axis, −150, and +150 indicate one end and the other end of the wafer W, respectively, and 0 indicates the center of the wafer W. The vertical axis indicates a calculated LWR, and the unit is nm. As illustrated in the graph, the wafer A2 shows a lower LWR than the wafer A1 at each of the measurement positions. That is, variation in roughness of the resist pattern on the surface of the wafer W is smaller.

In the present disclosure, the periods of time for gas supply may be matched with each other in a predetermined area of the wafer W in the same manner as in the apparatus used for processing the wafer A2. Thus, from the reference test result, it is thought that the roughness of the resist pattern may be improved with high in-plane uniformity of the wafer W in the apparatus of the present disclosure.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a processing chamber configured such that a substrate is processed by a processing gas under a normal pressure atmosphere within the processing chamber;
a disposition unit provided within the processing chamber and configured to dispose the substrate thereon; and
a gas supply unit provided to supply the processing gas to the substrate disposed on the disposition unit and having a gas ejecting surface facing the substrate,
wherein the gas supply unit includes:
a plurality of first gas ejecting holes and a plurality of second gas ejecting holes which are formed to be distributed over a first area and a second area of the gas ejecting surface,
first gas flow paths having an upstream side communicated with a common first gas supply hole and diverged on the way to have a downstream side opened as the plurality of first gas ejecting holes, and
second gas flow paths having an upstream side communicated with a common second gas supply hole and diverged on the way to have a downstream side opened as the plurality of second gas ejecting holes, the second gas flow paths being partitioned from the first gas flow paths, and
wherein a flow path length and a flow path diameter of each of the diverged first gas flow paths and the diverged second gas flow paths are set such that periods of time for gas flowing from the first gas supply hole to the respective first gas ejecting holes are matched with each other, and periods of time for gas flowing from the second gas supply hole to the respective second gas ejecting holes are matched with each other.

2. The substrate processing apparatus of claim 1, wherein, between the first gas flow paths and the second gas flow paths, at least the first gas flow paths are formed to be diverged in a stepwise diagram shape that determines a tournament combination from the first gas supply hole to the respective first gas ejecting holes.

3. The substrate processing apparatus of claim 2, wherein, assuming that a direction perpendicular to the substrate is defined as a vertical direction, between the first gas flow paths and the second gas flow paths, at least the first gas flow paths include:
a group of upper tier side flow paths that have a vertical flow path extending vertically and having an upper end side communicated with the first gas supply hole, and a plurality of horizontal flow paths extending horizontally and radially from a lower end side of the vertical flow path, and
a group of lower tier side flow paths that have a plurality of vertical flow paths extending downwardly from downstream ends of the horizontal flow paths, respectively, in the group of the upper tier side flow paths, and a plurality of horizontal flow paths extending radially and horizontally from lower end sides of the vertical flow paths.

4. The substrate processing apparatus of claim 3, wherein the gas supply unit includes a plurality of plates which are stacked one on another,
wherein the plurality of plates include a plate formed with groove portions or slits, and a plate formed with through holes that constitute the vertical flow paths, and the horizontal flow paths are formed by the groove portions or the slits formed on one plate together with a plate surface of another plate to be piled up on the plate.

5. The substrate processing apparatus of claim 2, wherein the first area and the second area face a central area of the substrate, and a circumferential edge area of the substrate, respectively.

6. The substrate processing apparatus of claim 2, wherein the processing performed on the substrate by supplying the processing gas is a processing performed to improve the roughness of a pattern mask formed on the substrate through exposure and development processings by supplying a solvent gas for dissolving a resist film on the substrate.

7. The substrate processing apparatus of claim 1, wherein assuming that a direction perpendicular to the substrate is defined as a vertical direction, between the first gas flow paths and the second gas flow paths, at least the first gas flow paths include:
a group of upper tier side flow paths that have a vertical flow path extending vertically and having an upper end side communicated with the first gas supply hole, and a plurality of horizontal flow paths, extending horizontally and radially from a lower end side of the vertical flow path, and
a group of lower tier side flow paths that have a plurality of vertical flow paths extending downwardly from downstream ends of the horizontal flow paths, respectively, in the group of the upper tier side flow paths, and a plurality of horizontal flow paths extending radially and horizontally from lower end sides of the vertical flow paths.

8. The substrate processing apparatus of claim 7, wherein the gas supply unit includes a plurality of plates which are stacked one on another,
wherein the plurality of plates include a plate formed with groove portions or slits, and a plate formed with through holes that constitute the vertical flow paths, and the horizontal flow paths are formed by the groove portions or the slits formed on one plate together with a plate surface of another plate to be piled up on the plate.

9. The substrate processing apparatus of claim 1, wherein the first area and the second area face a central area of the substrate, and a circumferential edge area of the substrate, respectively.

10. The substrate processing apparatus of claim 1, wherein the processing performed on the substrate by supplying the processing gas is a processing performed to improve the roughness of a pattern mask formed on the substrate through exposure and development processings by supplying a solvent gas for dissolving a resist film on the substrate.

11. A substrate processing apparatus comprising:
a processing chamber configured such that a substrate is processed by a processing gas under a normal pressure atmosphere within the processing chamber;
a disposition unit provided within the processing chamber and configured to dispose the substrate thereon; and
a gas supply unit provided to supply the processing gas to the substrate disposed on the disposition unit and having a gas ejecting surface facing the substrate.
wherein the gas supply unit includes:
a plurality of first gas ejecting holes and a plurality of second gas ejecting holes which are formed to be distributed over a first area and a second area of the gas ejecting surface,
first gas flow paths having an upstream side communicated with a common first gas supply hole and diverged on the way to have a downstream side opened as the plurality of first gas ejecting holes, the first gas flow paths being configured by using a plurality of plates which are stacked in a direction perpendicular to the substrate, and
second gas flow paths having an upstream side communicated with a common second gas supply hole, and diverged on the way to have a downstream side opened as the plurality of second gas ejecting holes, the second gas flow paths being configured by using the plurality of plates and partitioned from the first gas flow paths,
wherein, assuming that a direction perpendicular to the substrate is defined as a vertical direction, the first gas flow paths and the second gas flow paths each include:
a group of upper tier side flow paths that have a vertical flow path extending vertically and having an upper end side communicated with the first gas supply hole or the second gas supply hole, and a plurality of horizontal flow paths extending horizontally and radially from a lower end side of the vertical flow path, and
a group of lower tier side flow paths that have a plurality of vertical flow paths extending downwardly from downstream ends of the horizontal flow paths, respectively, in the group of the upper tier side flow paths, and a plurality of horizontal flow paths extending radially and horizontally from lower end sides of the vertical flow paths,
wherein the plurality of plates include a plate formed with groove portions or slits and a plate formed with through holes that constitute the vertical flow paths, and the horizontal flow paths are formed by the groove portions or the slits formed on one plate together with a plate surface of another plate to be piled up on the plate, and
wherein flow path lengths of the first gas flow paths from the first gas supply hole to the respective first gas ejecting holes are matched with each other, and flow path lengths of the second gas flow paths from the second gas supply hole to the respective second gas ejecting holes are matched with each other.

12. The substrate processing apparatus of claim 11, wherein a flow path length and a flow path diameter of each of the diverged first gas flow paths and the diverged second gas flow paths are set such that periods of time for gas flowing from the first gas supply hole to the respective first gas ejecting holes are matched with each other, and periods of time for gas flowing from the second gas supply hole to the respective second gas ejecting holes are matched with each other.

13. The substrate processing apparatus of claim 12, wherein the first area and the second area face a central area of the substrate, and a circumferential edge area of the substrate, respectively.

14. The substrate processing apparatus of claim 12, wherein the processing performed on the substrate by supplying the processing gas is a processing performed to improve the roughness of a pattern mask formed on the substrate through exposure and development processings by supplying a solvent gas for dissolving a resist film on the substrate.

15. The substrate processing apparatus of claim 11, wherein the first area and the second area face a central area of the substrate, and a circumferential edge area of the substrate, respectively.

16. The substrate processing apparatus of claim 11, wherein the processing performed on the substrate by supplying the processing gas is a processing performed to improve the roughness of a pattern mask formed on the substrate through exposure and development processings by supplying a solvent gas for dissolving a resist film on the substrate.

17. A gas supply apparatus comprising:
a processing container set to a normal pressure atmosphere and configured such that a processing gas is supplied to a substrate disposed within the processing container;
a gas ejecting surface facing the substrate disposed within the processing container;
a plurality of first gas ejecting holes and a plurality of second gas ejecting holes which are formed to be distributed over a first area and a second area of the gas ejecting surface, respectively,
first gas flow paths having an upstream side communicated with a common first gas supply hole and diverged on the way to have a downstream side opened as the plurality of first gas ejecting holes, and
second gas flow paths having an upstream side communicated with a common second gas supply hole and diverged on the way to have a downstream side opened as the plurality of second gas ejecting holes, the second gas flow paths being partitioned from the first gas flow paths,
wherein a flow path length and a flow path diameter of each of the diverged first gas flow path and the diverged second gas flow path are set such that periods of time for gas flowing from the first gas supply hole to the respective first gas ejecting holes are matched with each other, and periods of time for gas flowing from the second gas supply hole to the respective second gas ejecting holes are matched with each other.

18. A gas supply apparatus comprising:
a processing container set to a normal pressure atmosphere and configured such that a processing gas is supplied to a substrate disposed within the processing container;
a gas ejecting surface facing the substrate disposed within the processing container;
a plurality of first gas ejecting holes and a plurality of second gas ejecting holes which are formed to be distributed over a first area and a second area of the gas ejecting surface, respectively,
first gas flow paths having an upstream side communicated with a common first gas supply hole and diverged on the way to have a downstream side opened as the plurality of first gas ejecting holes, the first gas flow paths being configured by using a plurality of plates which are stacked in a direction perpendicular to the substrate, and
second gas flow paths having an upstream side communicated with a common second gas supply hole and diverged on the way to have a downstream side opened as the plurality of second gas ejecting holes, the second gas flow paths being configured by using the plurality of plates and partitioned from the first gas flow paths,
wherein, assuming that a direction perpendicular to the substrate is defined as a vertical direction, each of the first gas flow paths and the second gas flow paths includes:
a group of upper tier side flow paths that have a vertical flow path extending vertically and having an upper end side communicated with the first gas supply hole or the second gas supply hole, and a plurality of horizontal flow paths extending horizontally and radially from a lower end side of the vertical flow path, and
a group of lower tier side flow paths which have a plurality of vertical flow paths extending downwardly from downstream ends of the horizontal flow paths, respectively, in the group of the upper tier side flow paths, and a plurality of horizontal flow paths extending radially and horizontally from lower end sides of the vertical flow paths,
wherein the plurality of plates include a plate formed with groove portions or slits and a plate formed with through holes that constitute the vertical flow paths, and the horizontal flow paths are formed by the groove portions or the slits formed on one plate together with a plate surface of another plate to be piled up on the plate form the horizontal flow paths, and
wherein flow path lengths of the first gas flow paths from the first gas supply hole to the respective first gas ejecting holes are matched with each other, and flow path lengths of the second gas flow paths from the second gas supply hole to the respective second gas ejecting holes are matched with each other.
